(19) United States
(12) Patent Application Publication
(10) Pub. No.: US 2012/0275099 A1
(43) Pub. Date: Nov. 1, 2012

(54) PORTABLE ELECTRONIC DEVICE

(75) Inventors: Takashi Yamami, Daito-shi (JP); Junji Tanaka, Daito-shi (JP); Akito Iwai, Daito-shi (JP)

(73) Assignee: KYOCERA CORPORATION, Kyoto (JP)

(21) Appl. No.: 13/512,310

(22) PCT Filed: Nov. 26, 2010
(86) PCT No.: PCT/JP2010/071107

§ 371 Date: May 25, 2012

(30) Foreign Application Priority Data
Nov. 26, 2009 (JP) 2009-268394
Nov. 26, 2009 (JP) 2009-268395

(51) Int. Cl. H05K 7/00

(52) U.S. Cl. 361/679.01

(57) ABSTRACT

A portable electronic device in which a pair of housings are coupled and movable between a fully closed state and a fully open state, and electronic components contained in first and second housings are connected by using a flexible lead, the portable electronic device being able to accommodate a bending displacement of the flexible lead in association with relative movement of both housings without providing a large space inside the device. The portable electronic device includes a coupling arm which couples the first and second housing so as to be relatively movable between a fully closed state and a fully open state; a flexible lead includes a belt-like lead portion extending through the inside of the coupling arm; and the coupling arm is formed with a lead accommodating portion for tolerating a bending deformation of the lead portion in association with opening and closing of both the housings.

### TECHNICAL FIELD

The present invention relates to a portable electronic device comprising a pair of housings coupled to each other.

### BACKGROUND ART

As portable electronic devices comprising a pair of housings coupled to each other, conventionally known are portable electronic devices in which each of the housings has an image display surface and both the image display surfaces allow a large volume of information to be provided to the users.

In such a portable electronic device, for example, both housings make a relative movement respectively to each other between: a fully closed state in which the pair of housings are placed one on top of the other and the image display surface (first image display surface) of the lower housing (first housing) is covered with the upper housing (second housing) so that only the image display surface (second image display surface) of the second housing is exposed; and a fully open state in which the second housing is moved in relation to the first housing such that the image display surfaces of both the housings are exposed and the second image display surface is aligned with the first image display surface on the same plane.

In the fully open state, the image display surfaces of both the housings are aligned on the same plane, thereby image display with a large screen is possible by using the two image display surfaces as a single screen.

Incidentally, in a folding-type portable electronic devices including two housings that are openably and closably coupled, it is necessary to electrically connect an electronic component contained in one housing and an electronic component contained in the other housing with each other and, generally, connection by use of a flexible lead is adopted.

In a portable electronic device capable of setting a fully closed state in which a pair of housings are placed one on top of the other and only one image display surface is exposed as described above, and a fully open state in which both the housings make a relative movement such that the two image display surfaces are exposed on the same plane, however, there is a problem in that since the distance between the two electronic components to be connected with each other by the flexible lead significantly varies between the fully closed state and the fully open state, a large margin needs to be set to the length of the flexible lead which extends between both the housings, and a large space to tolerate the bending displacement of the flexible lead is required inside the device main body since the long flexible lead undergoes bending displacement as both the housings relatively move, thus leading to an upsizing of the device.

Moreover, since there is no common portion between an overlapping region of the two housings in a fully closed state and an overlapping region of the two housing in a fully open state, this may cause a problem of exposing the flexible lead, which extends between the two housings, to the outside in association with the shifting between the fully closed state and the fully open state.

### SUMMARY OF THE INVENTION

Accordingly, a first object of the present invention is to provide a portable electronic device in which a pair of housings are coupled so as to be relatively movable between a fully closed state and a fully open state, and an electronic component contained in one housing and an electronic component contained in the other housing are connected with each other by using a flexible lead, the portable electronic device configured to be able to tolerate a bending displacement of the flexible lead in association with relative movement of both the housings without providing a large space inside the device main body.

A second object of the present invention is to provide a portable electronic device in which a pair of housings are coupled so as to be relatively movable between a fully closed state and a fully open state, and an electronic component contained in one housing and an electronic component contained in the other housing are connected with each other by using a flexible lead, the portable electronic device configured such that the flexible lead will not be exposed to the outside even by an opening/closing action.

In a first portable electronic device relating to the present invention, a first housing and a second housing are coupled with each other via a coupling mechanism, and an image display surface is provided respectively on front faces of both the housings, the portable electronic device configured to be able to selectively set at least two states including: a fully closed state in which the image display surface of the first housing is covered with a back face of the second housing and the image display surface of the second housing is exposed; and a fully open state in which the second housing is moved from the fully closed state and the image display surfaces of both the housings are exposed.

The above described coupling mechanism includes a coupling arm which couples the first housing with the second housing so as to be relatively movable between the fully closed state and the fully open state; an electronic component contained in the first housing, and an electronic component contained in the second housing are electrically connected with each other via a flexible lead; the flexible lead having a belt-like lead portion extending through the inside of the coupling arm; and the coupling arm is formed with a lead accommodating portion for accommodating a bending deformation of the lead portion in association with opening and closing of both the housings.

In a specific embodiment, the first housing and the second housing can be further set in a tilted state in which the second housing is moved from the fully closed state to expose the image display surfaces of both the housings, and the image display surface of the second housing is tilted at an opening angle of not less than 90 degrees and less than 180 degrees with respect to the image display surface of the first housing.

In the above-mentioned portable electronic device, since the flexible lead is configured so that the lead portion extends through the inside of the coupling arm, when the coupling arm pivots in association with a relative movement of both the housings, the lead portion are bent and displaced in association with the pivoting of the coupling arm.

At this time, a slack is generated with respect to the length of flexible lead as both the housings move from the fully closed state to the fully open state, but the slack will be absorbed by bending deformation of the lead portion of the flexible lead generated in the lead accommodating portion of the coupling arm.

In a specific embodiment, the above described coupling arm has an L-shaped geometry which bends into an L-shape on the plane that perpendicularly intersects with the image display surfaces of both the housings, and includes a first arm portion and a second arm portion which intersect with each other at a corner portion of the L-shaped geometry; the end portion of the first arm portion is coupled to the rear end portion of the first housing with a first pivot axis, and the end portion of the second arm portion is coupled to a middle portion of the second housing between the front end portion and the rear end portion with a second pivot axis which is parallel with the first pivot axis; and the lead accommodating portion is formed in the end portion on the second housing side of the second arm portion.

Moreover, the flexible lead is drawn out from the rear end portion of the first housing, further extends along the first arm portion of the coupling arm, and is drawn into the inside of the second housing from the end portion of the second arm portion.

According to the specific embodiment, the lead portion of the flexible lead undergoes a bending deformation in the lead accommodating portion of the coupling arm in association with the shifting from the fully closed state to the fully open state, and undergoes bending deformation into a U-shape changing its course in the lead accommodating portion to be drawn into the inside of the second housing from the end portion of the second arm portion in the fully open state.

In a second portable electronic device relating to the present invention, a first housing and a second housing are coupled with each other via a coupling mechanism, and an image display surface is provided on the front face of each of both the housings, the second portable electronic device configured to be able to selectively set at least two states including: a fully closed state in which the image display surface of the first housing is covered with the back face of the second housing, and the image display surface of the second housing is exposed; and a fully open state in which the second housing is moved from the fully closed state so that both the image display surfaces are exposed.

The above described coupling mechanism comprises a coupling member that couples the first housing with the second housing so as to be relatively movable between the fully closed state and the fully open state described above; an electronic component contained in the first housing and an electronic component contained in the second housing are electrically connected with each other via a flexible lead, the flexible lead extending from the inside of the first housing into the inside of the second housing through inside of the above described coupling member; and the first housing is formed with an opening which is opened and closed by the reciprocating movement of the coupling member in association with the relative movement of both the housings, and is attached with a cover member that reciprocatingly moves in association with the reciprocating movement of the coupling member so that the cover member closes the opening while the coupling member opens the opening.

In a specific embodiment, the cover member is pivotably supported to the first housing and is rotationally biased in the direction to close the opening; and wherein the cover member opens the opening by being pressed by the coupling member in the process that the coupling member closes the opening in association with the shifting from the fully closed state to the fully open state, and the cover member is moved by the rotational biasing to close the opening in the process that the coupling member opens the opening in association with the shifting from the fully open state to the fully closed state.

In a further specific embodiment, the coupling member is configured such that a pair of left and right coupling arm portions are provided at both ends of the arm coupling portion so as to project therefrom; both ends of each coupling arm are coupled to both the housings; the flexible lead extends from the arm coupling portion along one coupling arm, and the opening is opened/closed by the arm coupling portion.

In the above described portable electronic device relating to the present invention, while in the process that the coupling member moves in association with the opening/closing action of the first housing and the second housing to reach a fully closed state from a fully open state, the coupling member will become spaced apart from the opening of the first housing thereby opening the opening; the cover member will approach to the opening in association with the movement of the coupling member, thus closing the opening. Moreover, while in the process to reach the fully open state from the fully closed state, the coupling member will approach to the opening of the first housing thereby closing the opening, the cover member will become spaced apart from the opening thereby closing the opening in association with the movement of the coupling member.

Thus, regardless of the open/closed state of both the housings, the opening of the first housing is closed by either one of the coupling member or the cover member, and the flexible lead, which is located in the inner portion of the opening, will never be exposed to the outside.

According to the first portable electronic device relating to the present invention, it is possible to tolerate the bending deformation of a flexible lead in association with the relative movement of both housings by only forming a lead accommodating portion in the coupling arm for coupling both the housings without providing a space for the bending deformation of the flexible lead in both the housings.

Moreover, according to the second portable electronic device relating to the present invention, the flexible lead will not be exposed to the outside even by the opening/closing action of the first housing and the second housing.

### BRIEF DESCRIPTION OF THE DRAWINGS

FIG. 1 is a perspective view showing a fully closed state of a portable electronic device relating to the present invention;

FIG. 2 is a turned over perspective view showing the portable electronic device in a fully closed state;

FIG. 3 is a perspective view showing a tilted state of the portable electronic device;

FIG. 4 is a perspective view of the tilted state of the portable electronic device seen from the rear face side thereof;

FIG. 5 is a perspective view showing a pivoting fully open state of the portable electronic device;

FIG. 6 is a turned over perspective view showing the portable electronic device in a pivoting fully open state;

FIG. 7 is a perspective view showing a sliding fully open state of the portable electronic device;

FIG. 8 is a turned over perspective view showing the portable electronic device in a sliding fully open state;

FIG. 9 is an exploded perspective view of the portable electronic device;

FIG. 10 is an exploded perspective view of the portable electronic device being in the state of being turned over;

FIG. 11 is a perspective view of the portable electronic device which is partially disassembled further from the state of FIG. 10;

FIG. 12 is a perspective view of the portable electronic device which is partially disassembled further from the state of FIG. 11;

FIG. 13 is a perspective view of a front cabinet making up the first housing and a front cabinet making up the second housing;

FIG. 14 is a turned over perspective view of the front cabinet making up the first housing and the front cabinet making up the second housing;

FIG. 15 is a perspective view showing a magnet on the second housing;

FIG. 16 is a perspective view showing a sliding member on the second housing;

FIG. 17 is a sectional view of the portable electronic device;

FIG. 18 is a sectional view taken along the line A-A of FIG. 1;

FIG. 19 is a sectional view taken along the line B-B of FIG. 1;

FIG. 20 is a sectional view showing an enlarged part of the second housing;

FIG. 21 is a perspective view of the portable electronic device a part of which is disassembled from the state of FIG. 6;

FIG. 22 is a perspective view of the portable electronic device a part of which is disassembled from the state of FIG. 8;

FIG. 23 is a sectional view showing a shifting from a pivoting fully open state (a) to a sliding fully open state (b) of the portable electronic device;

FIG. 24 is another sectional view showing a shifting from a pivoting fully open state (a) to a sliding fully open state (b) of the portable electronic device;

FIG. 25 is a sectional view showing an enlarged principal portion of FIG. 24;

FIG. 26 is a sectional view showing an enlarged abutment portion of both the housings in a sliding fully open state;

FIG. 27 is a series of side views showing the former half of the process reaching a sliding fully open state from a fully closed state via a tilted state of the portable electronic device relating to the present invention;

FIG. 28 is a series of side views showing the latter half of the same process as described above;

FIG. 29 is side views showing the states in which the portable electronic device relating to the present invention is placed on a desk in a tilted state (a) and in a sliding fully open state (b);

FIG. 30 is a perspective view showing the accommodating state of a flexible lead in a fully closed state;

FIG. 31 is a perspective view showing the accommodating state of the flexible lead in a tilted state;

FIG. 32 is a perspective view showing the accommodating state of the flexible lead in a pivoting fully open state;

FIG. 33 is a perspective view showing the accommodating state of the flexible lead in a sliding fully open state;

FIG. 34 is a perspective view showing the flexible lead extending in a coupling arm;

FIG. 35 is a perspective view showing a lead accommodating portion in the coupling arm;

FIG. 36 is a series of side views showing the state of the bending displacement of the flexible lead in the former half of the process to reach a sliding fully open state from a fully closed state through a tilted state;

FIG. 37 is a series of side views showing the state of the bending displacement of the flexible lead in the latter half of the same process as describe above;

FIG. 38 is an exploded perspective view of the first housing in the state in which a cover member is attached;

FIG. 39 is a perspective view of the first housing in the state in which the cover member is removed;

FIG. 40 is an enlarged perspective view of the cover member;

FIG. 41 is an enlarged sectional view showing the posture of the cover member in a fully closed state;

FIG. 42 is an enlarged sectional view showing the posture of the cover member in a sliding fully open state; and

FIG. 43 is a diagram showing a state (a) in which an opening is closed by the cover member of the first housing, and a state (b) in which the flexible lead is exposed from the opening.

### BEST MODE FOR CARRYING OUT THE INVENTION

Hereafter, embodiments of the present invention will be specifically described with reference to the drawings.

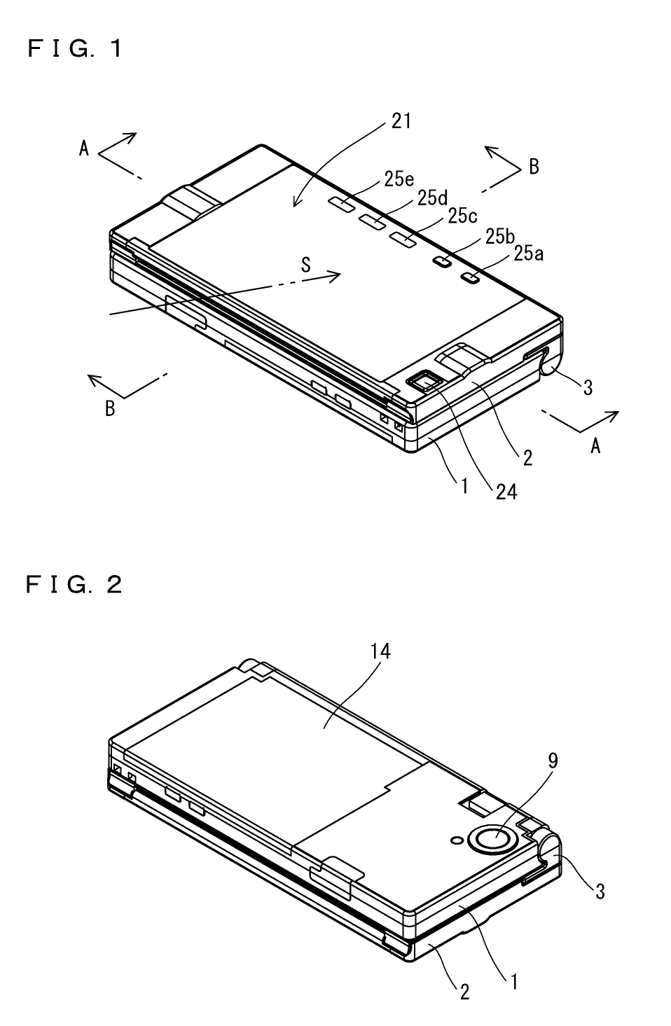

The portable electronic device relating to the present invention is configured such that a first housing 1 having a first image display surface 11 on its front face and a second housing 2 having a second image display surface 21 on its front face are coupled with each other via a coupling mechanism 3, as shown in FIGS. 1 to 8.

It is noted that when each site of components of the portable electronic device is specified in the following description, the “front (near side)”, “rear”, “left” and “right” when the portable electronic device of FIG. 1 is seen from a user's line of sight shown by an arrow S in the figure are also referred to as a “front”, “rear”, “left” and “right” in other drawings regardless of the posture of the portable electronic device.

As shown in FIG. 1, on the front face of the second housing 2, disposed in the right side portion and the rear end portion thereof are a cursor key 24 for moving a cursor, an END key 25a for an on-hook operation, a TALK key 25b for off-hook operation, a home key 25c for displaying a home screen, a menu key 25d for displaying a menu screen, and a BACK key 25e for moving the operation backward by one step. Here, the END key 25a and the TALK key 25b are mechanical switches and are accommodated in a concave portion formed in a front cabinet. In contrast to this, the home key 25c, the menu key 25d, and the BACK key 25e are software keys and are intended for operating a touch panel beneath the front cabinet via a through hole provided in the front cabinet.

Moreover, as shown in FIG. 2, a photographing lens 9 is disposed in the rear face of the first housing 1.

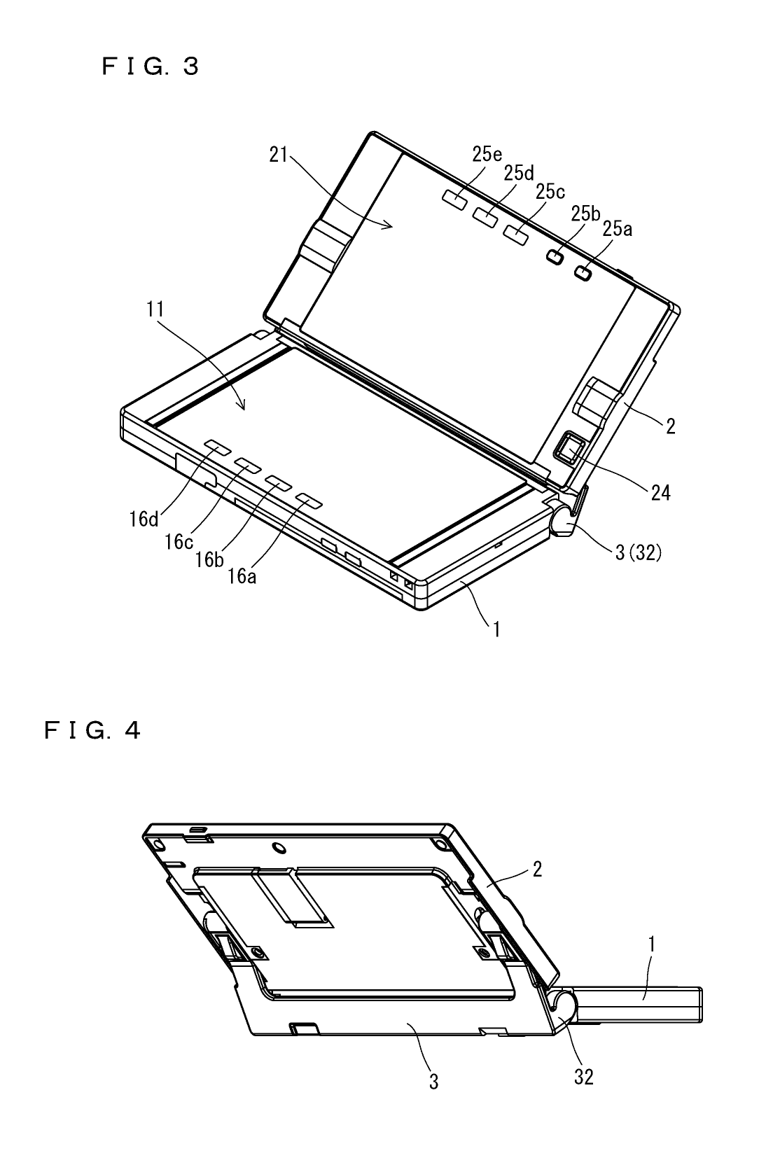

As shown in FIG. 3, on the front face of the first housing 1, there are disposed in the front end portion thereof a home key 16a, a menu key 16b, a BACK key 16c, and a view key 16d to be operated when switching the display between the first housing and the second housing. These operation keys are software keys and are intended for operating a touch panel beneath the front cabinet via a through hole provided in the front cabinet.

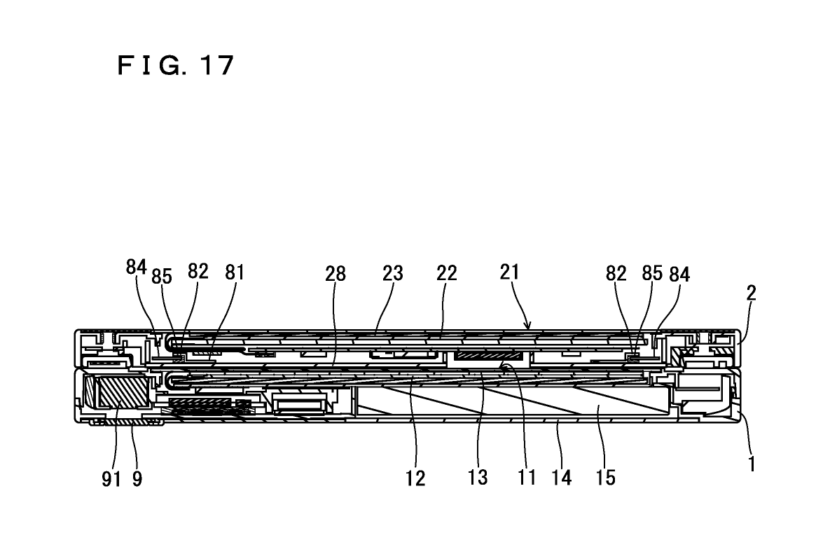

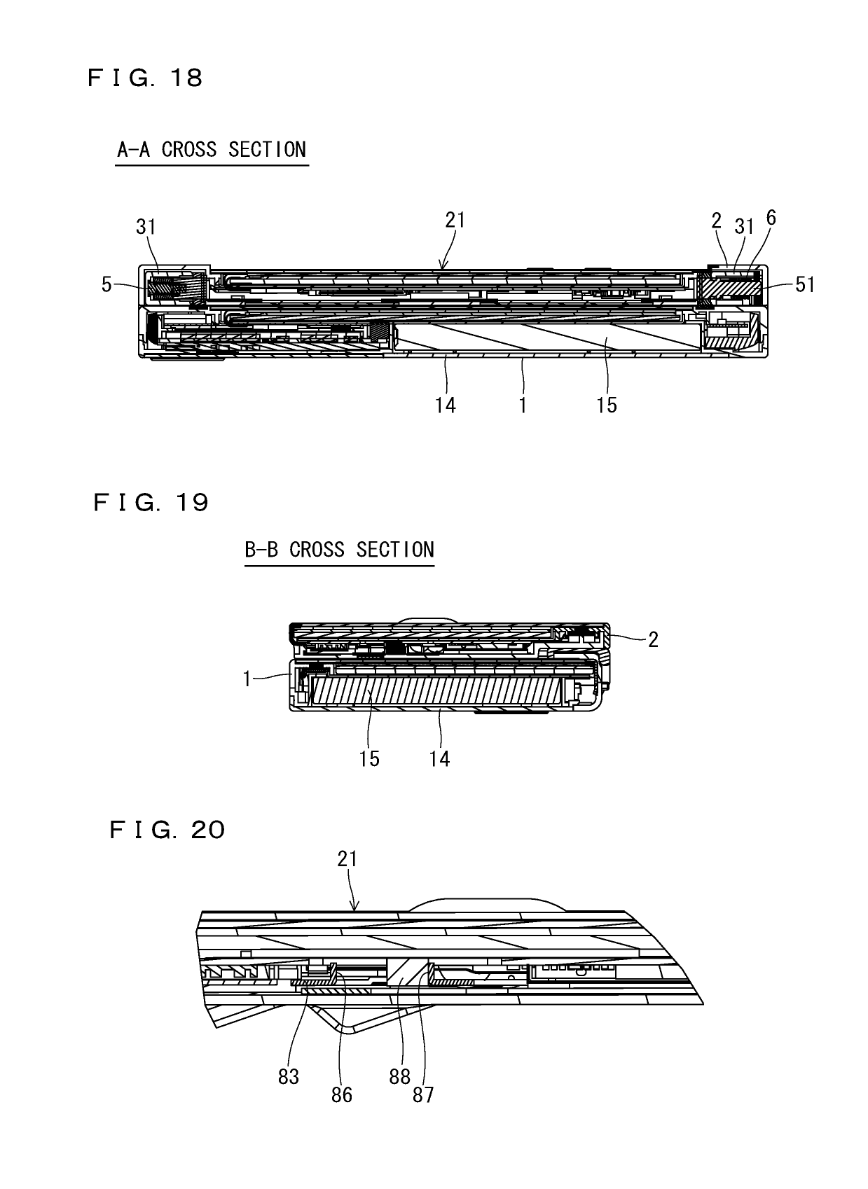

As shown in FIG. 17, inside the first housing 1, a first touch panel 13 and a first display 12 are disposed facing the first image display surface 11, and a camera 91 is disposed facing the photographing lens 9. Moreover, as shown in FIGS. 18 and 19, a battery 15 is accommodated inside the first housing 1, and the battery 15 is replaceable by removing a battery cap 14.

On the other hand, inside the second housing 2, a second touch panel 23 and a second display 22 are disposed facing the second image display surface 21 as shown in FIG. 17.

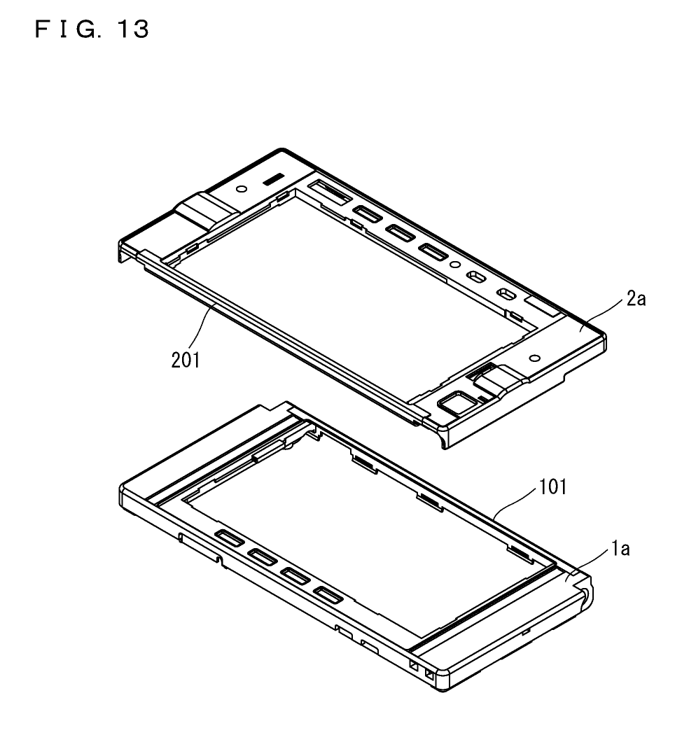

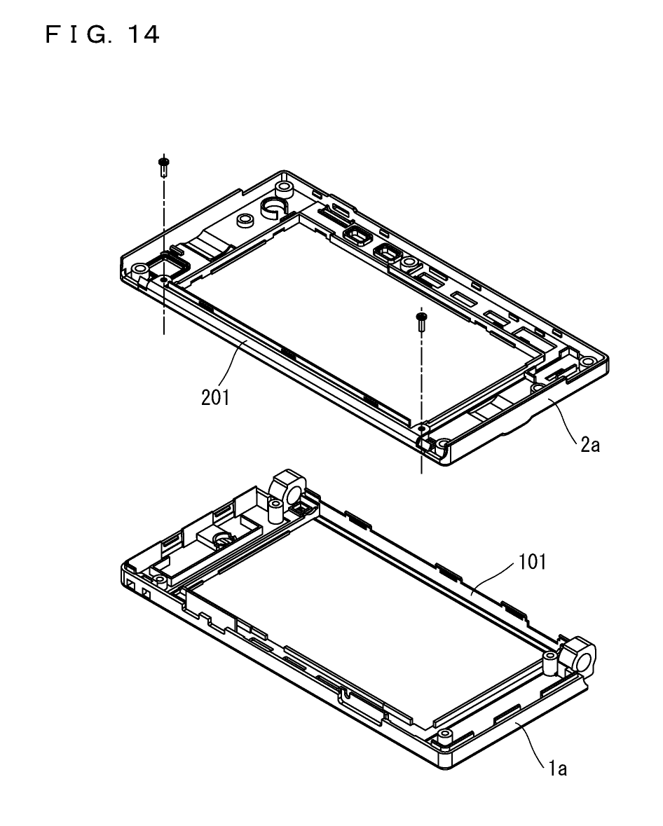

As shown in FIGS. 13 and 14, in the rear end portion of the front cabinet 1a making up the first housing 1, a metal plate 101 made of stainless steel, which forms a part of the front cabinet 1a, is secured by screws; and in the front end portion of the front cabinet 2a making up the second housing 2, a metal plate 201 made of stainless steel, which forms a part of the front cabinet 2a, is secured by screws. It is noted that the metal plates 101 and 201 may be secured by a fitting structure.

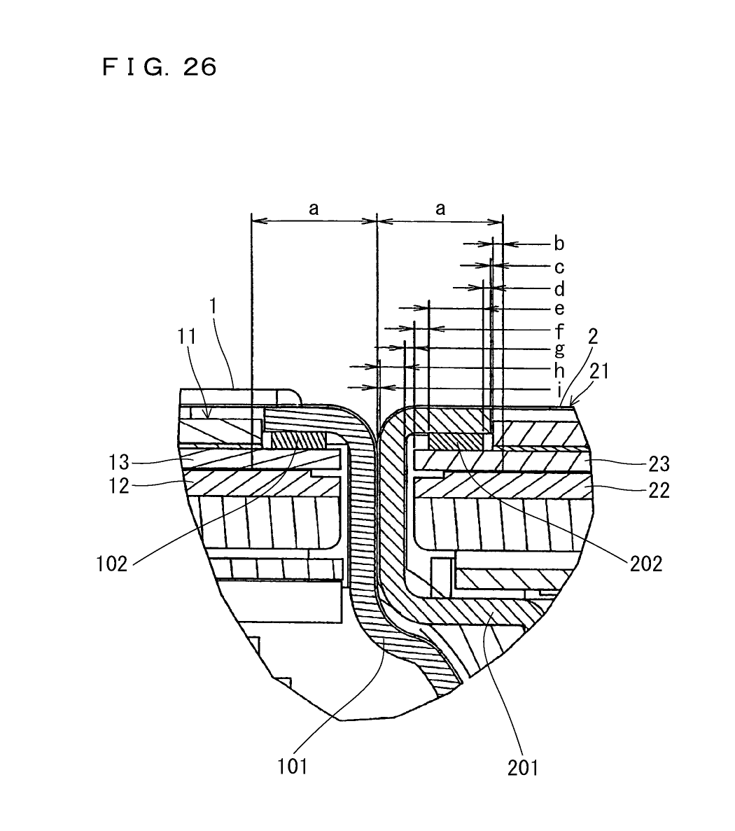

As shown in FIG. 26, the end portions of the metal plates 101 and 102 and the end portions of the touch panels 13 and 23 are secured by adhesion to each other by means of double-sided adhesive tapes 102 and 202.

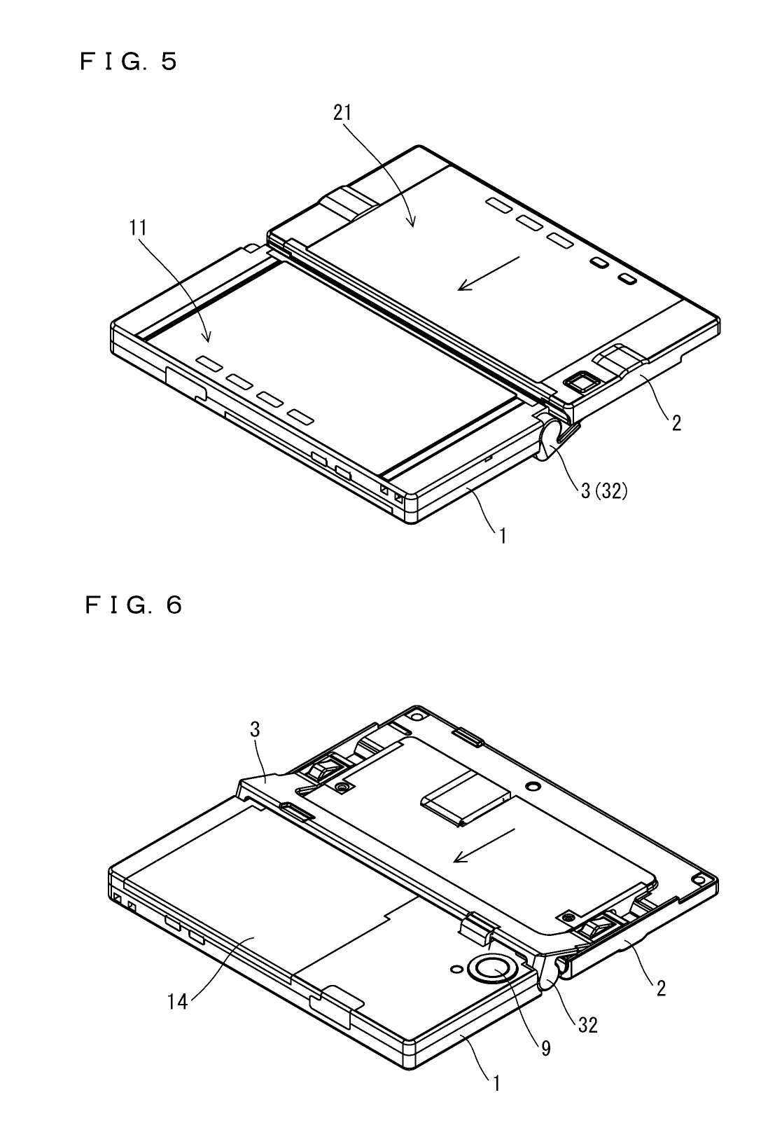

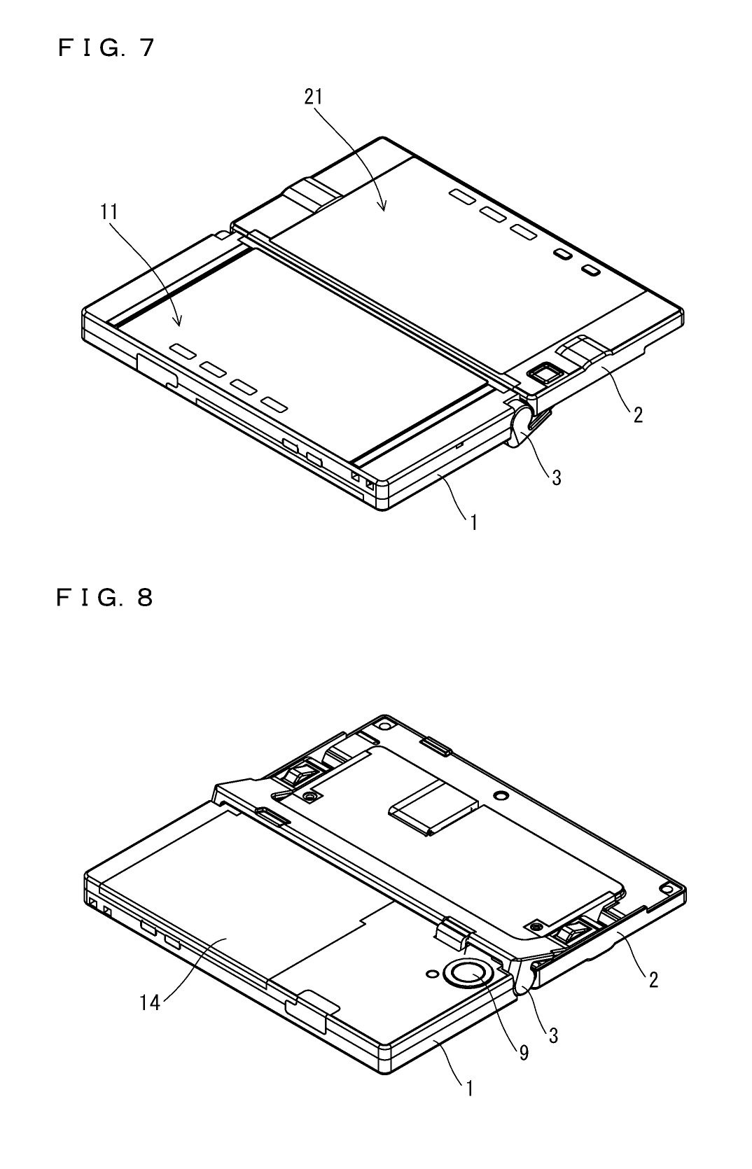

The portable electronic device relating to the present invention can be selectively set to four states: a fully closed state in which the front face of the first housing 1 is covered with the back face of the second housing 2, and the front face of the second housing 2 is exposed as shown in FIGS. 1 and 2; a tilted state in which the front faces of both the housings 1 and 2 are exposed by moving the second housing 2 backward as shown in FIGS. 3 and 4, and the front face of the second housing 2 is tilted with respect to the front face of the first housing 1 at an opening angle of not less than 90 degrees and less than 180 degrees as shown in FIGS. 3 and 4; a pivoting fully open state in which the front faces of both the housings 1 and 2 are exposed on the same plane by pivoting the second housing 2 backward as shown in FIGS. 5 and 6; and a sliding fully open state in which the second housing 2 is slid toward the first housing 1 with the front faces of both the housings 1 and 2 being exposed on the same plane as shown in FIGS. 7 and 8.

The coupling mechanism 3, which couples the first housing 1 and the second housing 2 with each other, includes: a U-shaped coupling member 32 which includes an arm coupling portion 32a extending to left and right; and a pair of left and right coupling arms 31 and 31 extending in the fore-and-aft direction, the coupling arms 31 and 31 being configured to project from both end portions of the arm coupling portion 32a, respectively.

The coupling arm 31 has an L-shape that bends into an L-shaped geometry on the plane that perpendicularly intersects with the image display surfaces of both the housings, and is made up of a first arm portion 35 and a second arm portion 36 which intersect with each other at the corner portion of the L-shaped geometry.

The proximal end portion of the right-side coupling arm 31 (the proximal end portion of the first arm portion 35) is coupled to the rear end portion of the right-side face of the first housing 1 via a known hinge unit 4 containing a spring and a cam mechanism, and the proximal end portion of the left-side coupling arm 31 (the proximal end portion of the first arm portion 35) is coupled to the rear end portion of the left-side face of the first housing 1 via a dummy hinge unit 41 containing no spring nor cam mechanism.

Moreover, the distal end portion of the right-side coupling arm 31 (the distal end portion of the second arm portion 36) is coupled to a rear-face right end portion of the second housing 2 via a first hinge member 5, and the distal end portion of the left-side coupling arm 31 (the distal end portion of the second arm portion 36) is coupled to the rear-face left end portion of the second housing 2 via the second hinge member 51.

Both the hinge members 5 and 51 are accommodated in the rear portion of the second housing 2 as shown in FIG. 18.

The hinge units 4 and 41 make up a first pivot axis that couples the proximal end portion of the coupling arm 31 to the first housing 1, and on the other hand, the hinge members 5 and 51 make up a second pivot axis that couples the distal end portion of the coupling arm 31 to the second housing 2 such that the first pivot axis and the second pivot axis are parallel with each other.

Further, the electronic components (a display, a touch panel, etc.) contained in the first housing 1 and the electronic components (a display, a touch panel, an IC, etc.) contained in the second housing 2 are electrically connected with each other with a flexible lead 7. The flexible lead 7 extends from the inside of the second housing 2 to the inside of the first housing 1 through the inside of the coupling arm 31, and the length thereof is given a margin that can tolerate a relative movement between the first housing 1 and the second housing 2.

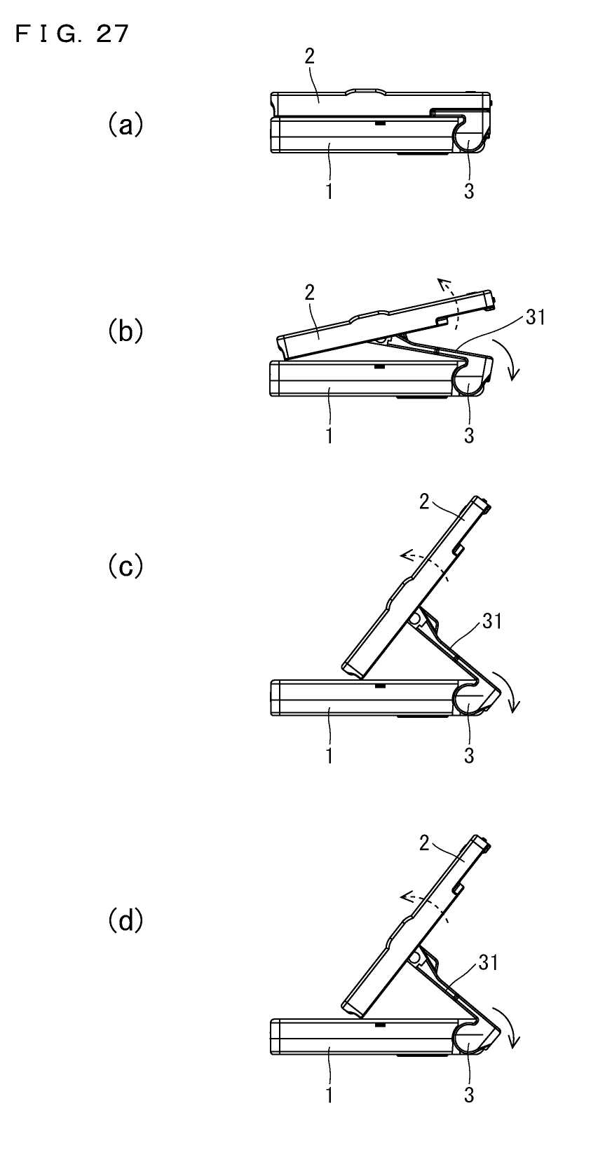

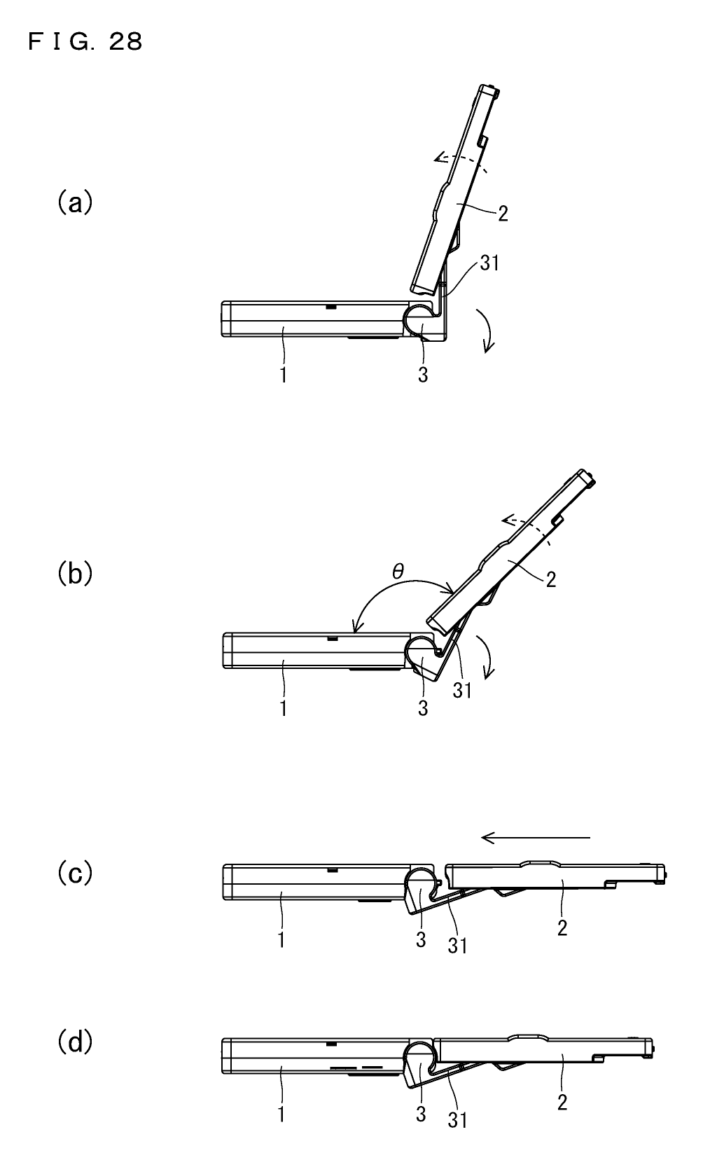

As a result of this, the second housing 2 can make a series of relative movements shown in FIGS. 27(a) to (d) and FIGS. 28(a) to (c) with respect to the first housing 1.

The hinge unit 4 softly engages the coupling member 32 with respect to the first housing 1 in the tilted state shown in FIGS. 3 and 4, and biases the coupling member 32 toward a rotational angle in the tilted state within a fixed angle range with a rotational angle in the tilted state being as the center. Moreover, the hinge unit 4 biases the coupling member 32 toward a rotational angle in a pivoting fully open state within a fixed angle range including the pivoting fully open state shown in FIGS. 5 and 6.

It is noted that in the pivoting fully open state shown in FIGS. 5 and 6, the coupling member 32 is held at a rotational angle of the pivoting fully open state by being received by the first housing 1.

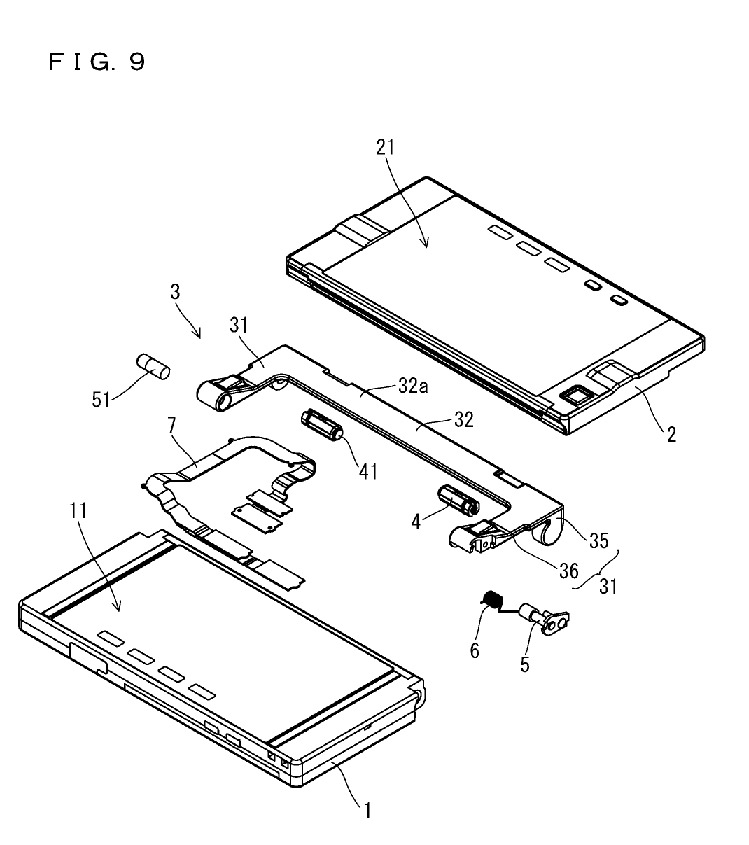

As shown in FIG. 9, a torsion spring 6 is attached to the first hinge member 5 with its rotational axis (the second pivot axis) as the center, and the second housing 2 is rotationally biased toward a direction to reduce the opening angle θ in a tilted state shown in FIG. 28(b) by the torsion spring 6.

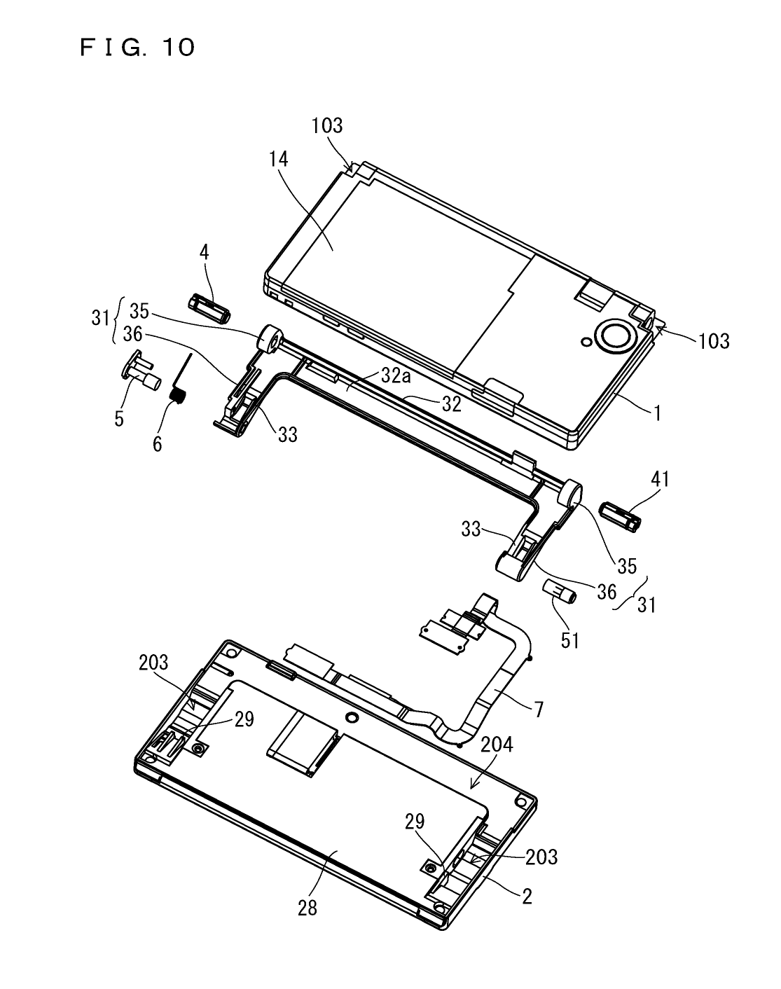

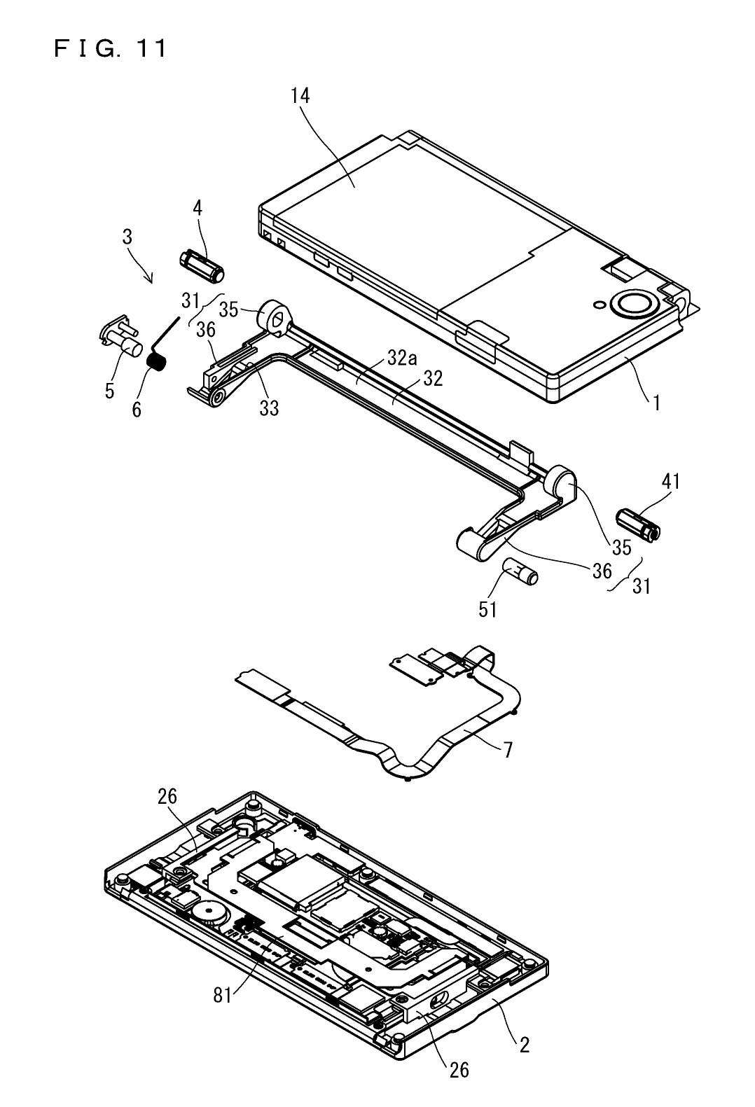

Moreover, as shown in FIG. 10, accommodating portions 103 and 103, which are to accommodate the first arm portions 35 and 35 of the coupling arms 31 and 31 of the coupling member 32, are provided in a depressed form in the rear end portions of both side faces of the first housing 1.

On the other hand, accommodating portions 204, 203, and 203, which are to accommodate an arm coupling portion 32a and second arm portions 36 and 36 of the coupling member 32, are provided in a depressed form in the both side portions of the rear face of the second housing 2.

Moreover, as shown in FIG. 10, both the coupling arms 31 and 31 of the coupling member 32 are respectively formed with a receiving surface 33 for receiving the second housing 2 in opposed portions to the second housing 2, and the both end portions of the rear face of the second housing 2 are respectively formed with slide surfaces 29 to be in sliding contact with the receiving surface 33.

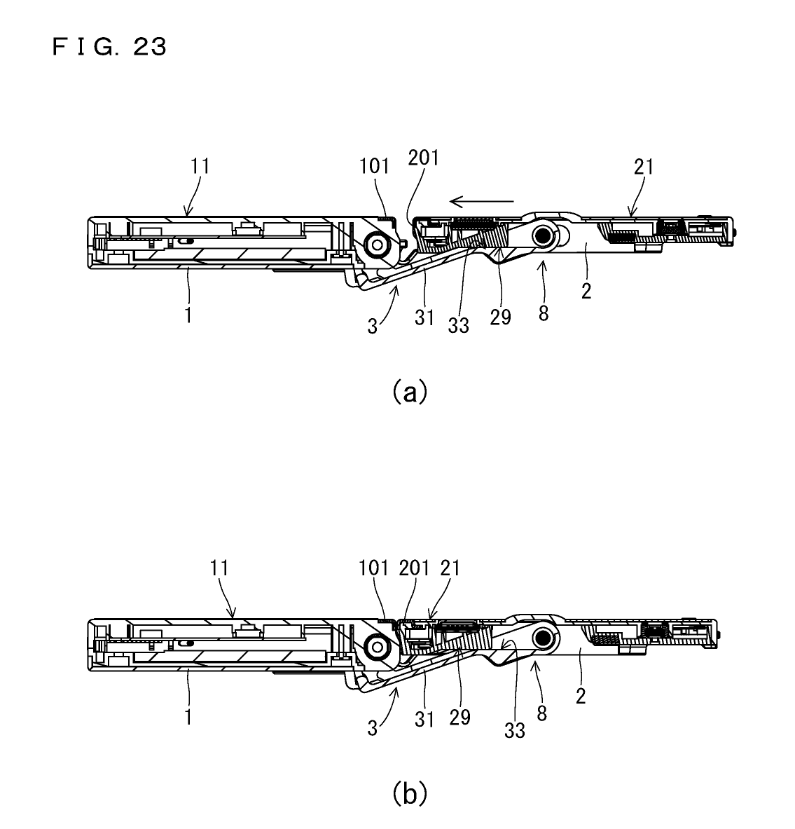

In the tilted state shown in FIGS. 3 and 4, and in the pivoting fully open state shown in FIGS. 5 and 6, the slide surface 29 of the second housing 2 comes into abutment with the receiving surface 33 of the coupling arm 31 as shown in FIG. 23(a) so that the pivoting of the second housing 2 with respect to the coupling arm 31 is stopped and thereby the relative posture of the second housing 2 with respect to the coupling arm 31 in the tilted state and the pivoting fully open state is specified.

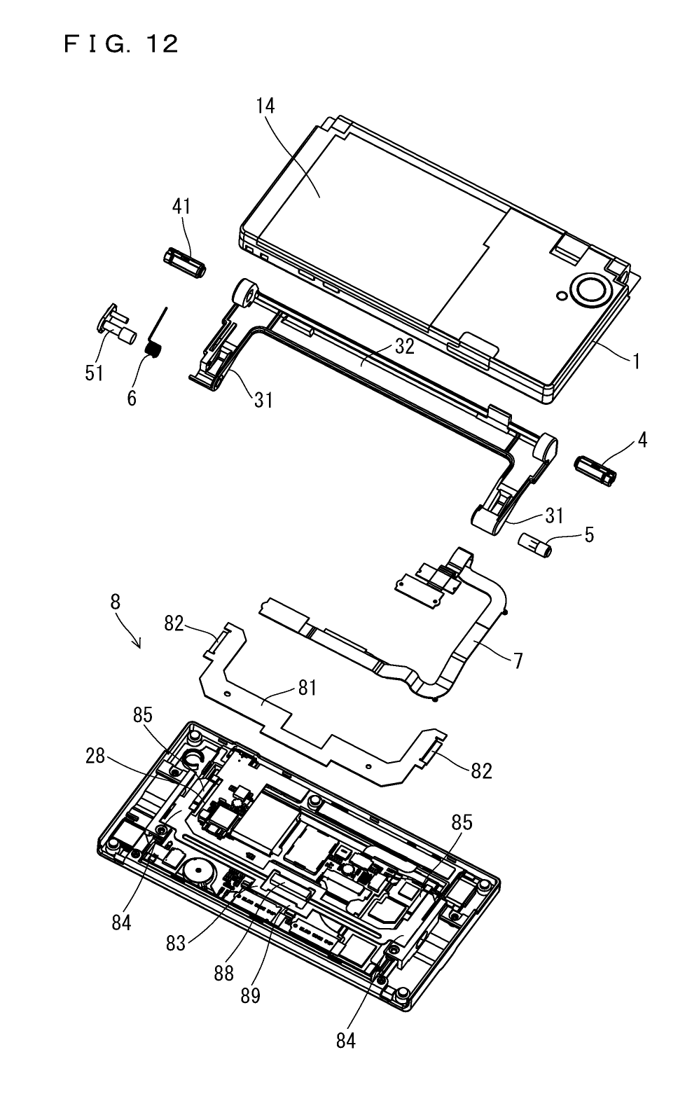

As shown in FIG. 12, a U-shaped slide member 83, which is slidable in the fore-and-aft direction, is disposed on the rear face panel 28 making up the second housing 2, and an U-shaped support member 81 is secured covering the slide member 83. Support arm portions 84 and 84 are provided in the left and right end portions of the slide member 83 so as to project therefrom, and slide guide portion 85 is provided in each support arm portion 84. Moreover, sliding portions 82 and 82 are provided in the left and right end portions of the support member 81 so as to project therefrom.

Further, the sliding guide portions 85 and 85, which are attached to the support arm portions 84 and 84, are sandwiched between the sliding portions 82 and 82 of the support member 81 and the rear face panel 28 as shown in FIG. 17, and the sliding in the fore-and-aft direction of the slide member 83 on the rear face panel 28 is guided.

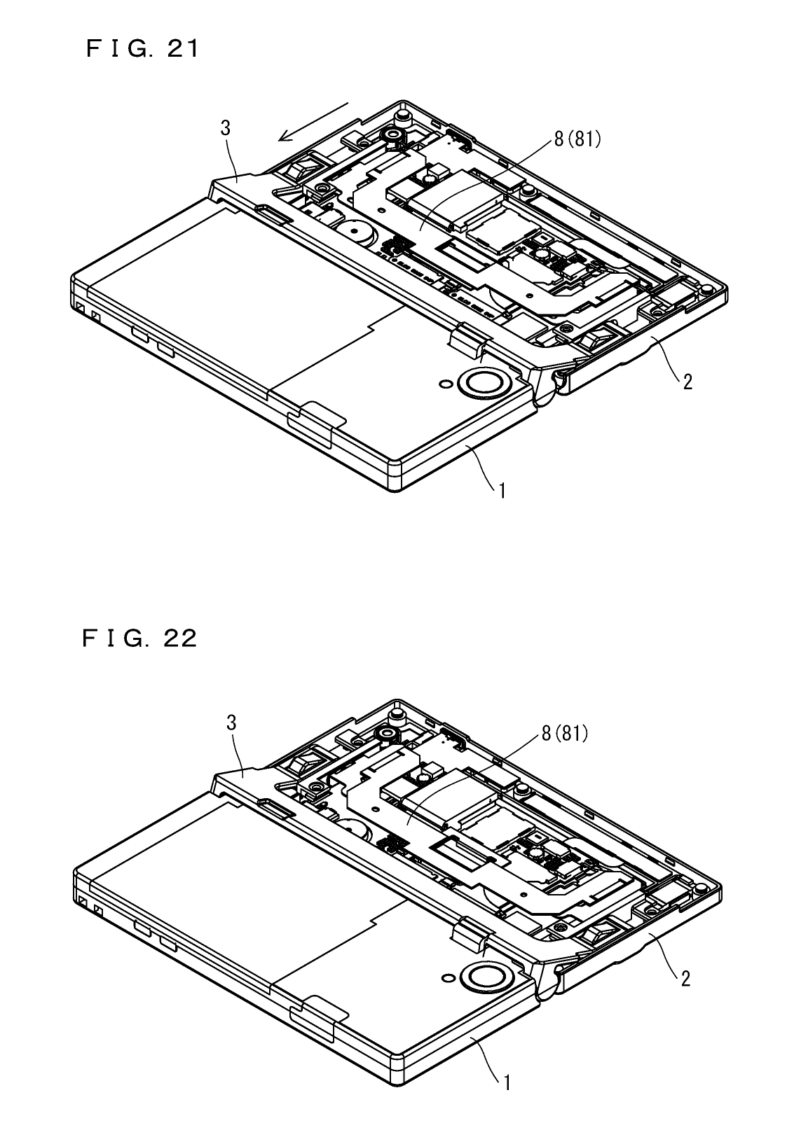

As a result of this, a slide mechanism 8, which causes the second housing 2 to slide in the fore-and-aft direction with respect to the support arm portions 84 and 84, is made up thus enabling that the second housing 2 slides in the fore-and-aft direction between the pivoting fully open state shown in FIGS. 5, 6, and 21 and the sliding fully open state shown in FIGS. 7, 8, and 22.

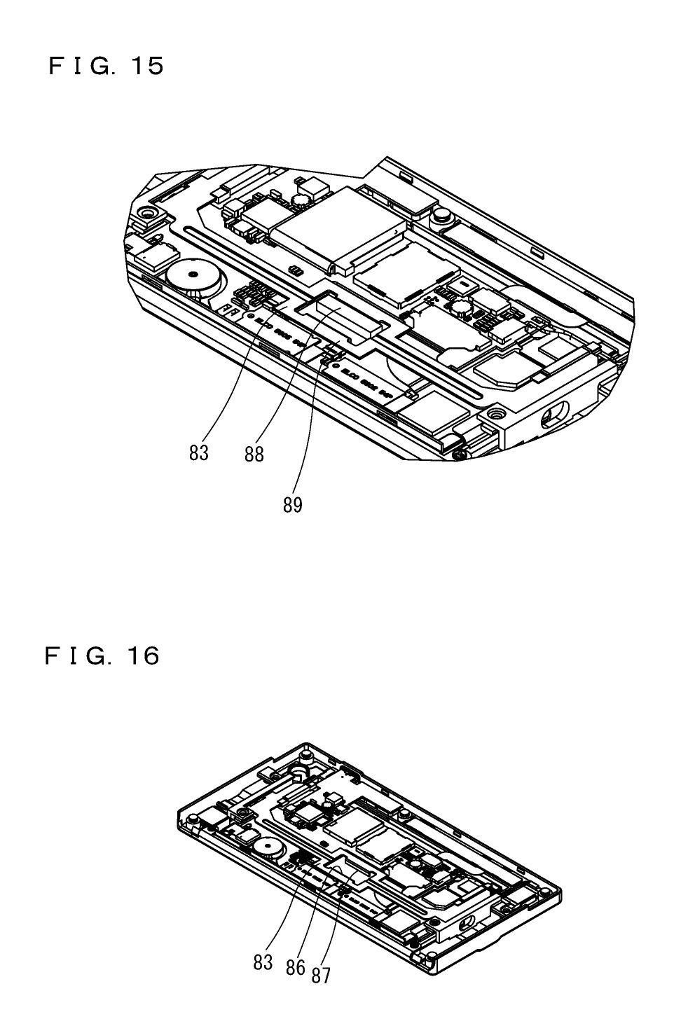

Moreover, while a magnet 88 is placed on the rear face panel 28, a frame portion 89 that surrounds the magnet 88 is formed as shown in FIG. 15 in the middle portion of the slide member 83, and the frame portion 89 is formed with a pair of projection pieces 86 and 87 as shown in FIG. 16 in front and the back of the magnet 88.

As a result of the slide member 83 sliding in the fore-and-aft direction as described above, either one of the pair of projection pieces 86 and 87 will come into contact with the magnet 88 as shown in FIG. 20.

As a result of this, either one of the pair of projection pieces 86 and 87 is adhered to the magnet 88 in each of the pivoting fully open state shown in FIGS. 5 and 6 and the sliding fully open state shown in FIGS. 7 and 8, and the magnetic attraction force allows the second housing 2 to be held at the sliding position in the pivoting fully open state or the sliding fully open state.

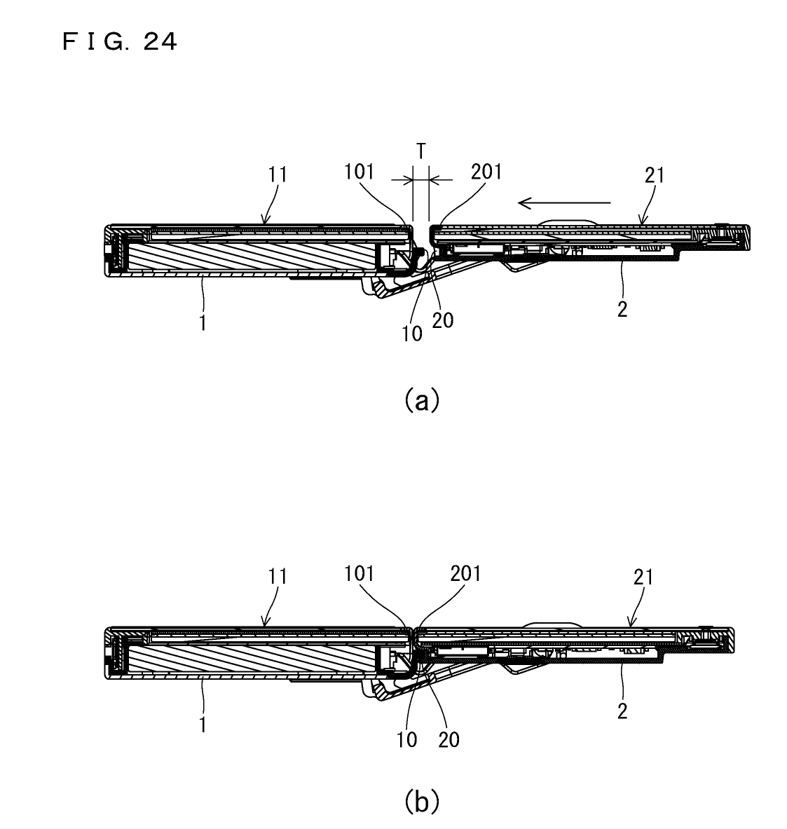

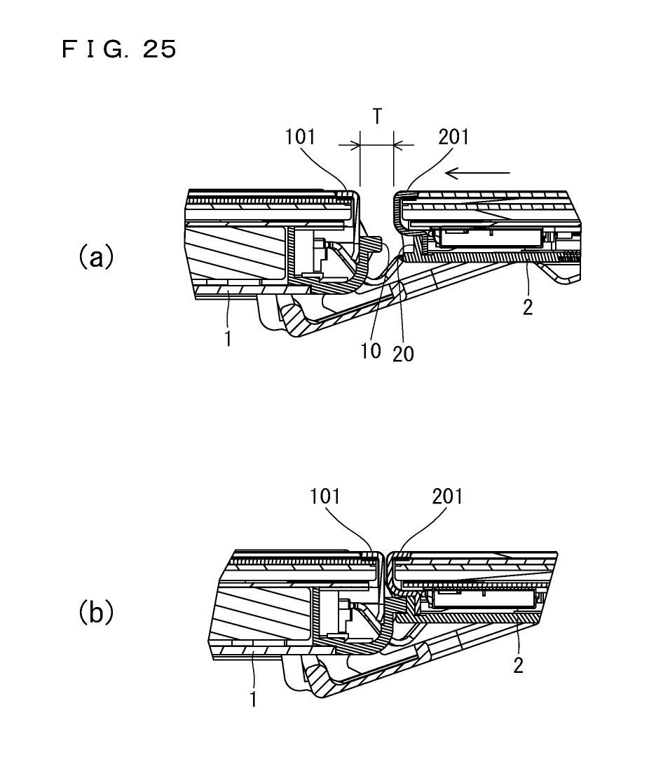

The rear end face of the first housing 1 and the front end face of the second housing 2, which are to face each other in a pivoting fully open state, are formed with a convex portion 10 and a concave portion 20, which are engageable and disengageable with each other as shown in FIGS. 24 (a) and (b) so that the convex portion 10 and the concave portion 20 are to be disengaged from each other in the pivoting fully open state as shown in FIGS. 24(a) and 25(a), and the convex portion 10 and the concave portion 20 are to be engaged with each other in the sliding fully open state as shown in FIGS. 24(b) and 25(b).

As a result of this, in the sliding fully open state shown in the FIGS. 24(b) and 25(b), the first housing 1 and the second housing 2 are coupled with each other through the engagement between the convex portion 10 and the concave portion 20, thereby maintaining a state in which the first image display surface 11 and the second image display surface 21 are aligned on the same plane.

While a gap T of a sufficient size (for example, of several millimeters) is provided between the metal plate 101 making up the first housing 1, and the metal plate 201 making up the second housing 2 in the pivoting fully open state as shown in FIGS. 24(a) and 25(a), both the metal plates 101 and 201 come to abut each other, or face each other at a slight distance (for example, 0.1 mm) in the sliding fully open state as shown in FIGS. 24(b) and 25(b).

In the sliding fully open state, the dimension of each portion shown in FIG. 26 is set to, for example, a: 2.55 mm, b: 0.2 mm, c: 0.05 mm, d: 0.15 mm, e: 1.1 mm, f: 0.3 mm, g: 0.2 mm, h: 0.5 mm, i: 0.05 mm.

Where, the dimension a is the distance from the end face of the cabinet to the image display area of the displays 12 and 22; the dimension b is a distance from the end edge of the image display surfaces 11 and 21 to the image display area; the dimension h is the thickness of the metal plates 101 and 201; and the dimension i is the amount of descent of the metal plates 101 and 201 from the cabinet surface.

According to the above described portable electronic device, the following four states can be selectively set: a fully closed state in which the first housing 1 and the second housing 2 are superposed one on top of the other, and only the second image display surface 21 is exposed as shown in FIGS. 1 and 2; a tilted state in which both the first display surface 11 and the second image display surface 21 are exposed by moving the second housing 2 backward from the fully closed state, and the second image display surface 21 is tilted with respect to the first image display surface 11 at an opening angle of not less than 90 degrees and less than 180 degrees as shown in FIGS. 3 and 4; a pivoting fully open state in which both the first display surface 11 and the second image display surface 21 are exposed on the same plane by pivoting the second housing 2 rearward from the above described tilted state as shown in FIGS. 5 and 6; and a sliding fully open state in which both the display surfaces 11 and 21 are exposed on the same plane by causing the second housing 2 to slide to the first housing 1 side from the above described pivoting fully open state causing the first image display surface 11 and the second image display surface 21 to come close to each other as shown in FIGS. 7 and 8.

In the fully closed state shown in FIGS. 1 and 2, the first arm portions 35 and 35 of the coupling arms 31 and 31 are accommodated in the accommodating portions 103 and 103 of the first housing 1 as shown in FIG. 10; and the arm coupling portion 32a of the coupling member 32 and the second arm portions 36 and 36 are accommodated in the accommodation portions 204, 203, and 203 of the second housing 2 so that the coupling mechanism 3 does not protrude from the both side faces or the rear end face of both the housings 1 and 2, and the whole device is packed into a compact size.

Moreover, even in any of the tilted state shown in FIG. 3, the pivoting fully open state shown in FIG. 5, and the sliding fully open state shown in FIG. 7, substantially the whole of the coupling mechanism 3 is hidden in the rear face sides of both the housings 1 and 2, the protruding portion of the coupling mechanism 3 will not be seen from a normal line of sight of user (arrow S in FIG. 1).

As shown in FIGS. 27(a) to (d) and FIGS. 28(a) to (d), in the process to cause the above described portable electronic device to shift from the fully closed state to the sliding fully open state via the tilted state and the pivoting fully open state, if the second housing 2 is pushed rearward and moved slightly in the fully closed state shown in FIG. 27(a), the second housing 2 will pivot in the counter clockwise direction as shown by the arrow of dotted line due to the biasing of the torsion spring 6 as shown in Figures (b) to (d), and accordingly the coupling arm 31 will rotate in the clockwise direction as shown by the arrow of solid line.

As a result of this, the second housing 2 will move rearward while the second image display surface 21 remains to face upward or diagonally upward.

Then, at the moment just after the state of FIG. 27(d) slightly passed, the coupling arm 31 further rotates in the clockwise direction as shown in FIG. 28(a) due to the biasing of the hinge unit 4, and is softly locked at a rotational angle of a tilted state as shown in FIG. 28(b). Moreover, the second housing 2 pivots in the counter clockwise direction due to the biasing by the torsion spring 6, and is held in a posture of the tilted state shown in FIG. 28 (b) by the slide surface 29 coming into abutment with the receiving surface 33 of the coupling arm 31.

Thus, only by a user pressing the second housing 2 rearward to move it slightly in the fully closed state shown in FIG. 27(a), thereafter, the second housing 2 will automatically move to a tilted state as shown in FIG. 28(b).

Next, if the second housing 2 is pressed rearward in the tilted state shown in FIG. 28(b) to rotate the coupling arm 31 slightly in the clockwise direction, then thereafter the coupling arm 31 will rotate up to the rotational angle of the pivoting fully open state shown in FIG. 28(c) due to the biasing by the hinge unit 4 while the slide surface 29 of the second housing 2 remains to be in abutment with the receiving surface 33 of the coupling arm 31, and will be received by the first housing 1 at this rotational angle.

In association with the rotation of the coupling arm 31, the second housing 2 pivots toward reward, eventually resulting in that the first image display surface 11 and the second image display surface 21 are aligned on the same plane.

Further, drawing the second housing 2 toward the first housing 1 from the pivoting fully open state will cause the slide surface 29 of the second housing 2 to slide on the receiving surface 33 of the coupling arm 31 as shown in FIGS. 23(a) and (b), and thereby the second housing 2 moves horizontally to the sliding fully open position shown in FIG. 28(d), eventually coming into abutment with the first housing 1.

As a result of this, the first image display surface 11 and the second image display surface 21 come closer to each other as shown in FIG. 7, and thereby one large screen will be formed by both the image display surfaces 11 and 21.

In the sliding fully open state, the convex portion 10 of the first housing 1 and the concave portion 20 of the second housing 2 engages with each other as shown in FIG. 24(b) thereby coupling both the housings 1 and 2. Thus, even if the second image display surface 21 is touch-operated strongly in this state, the second housing 2 will maintain a fixed posture with respect to the first housing 1.

Since a structure is adopted in which the metal plates 101 and 201 of both the housings 1 and 2 face each other in the sliding fully open state as shown in FIG. 26, the space between the first display 12 and the second display 22 can be reduced by a difference (1.4 mm) between the thickness (1.2 mm×2) of a synthetic resin cabinet and the thickness (0.5 mm×2) of metal plates compared with a general structure in which synthetic resin cabinets are caused to face each other without adopting the metal plates 101 and 201.

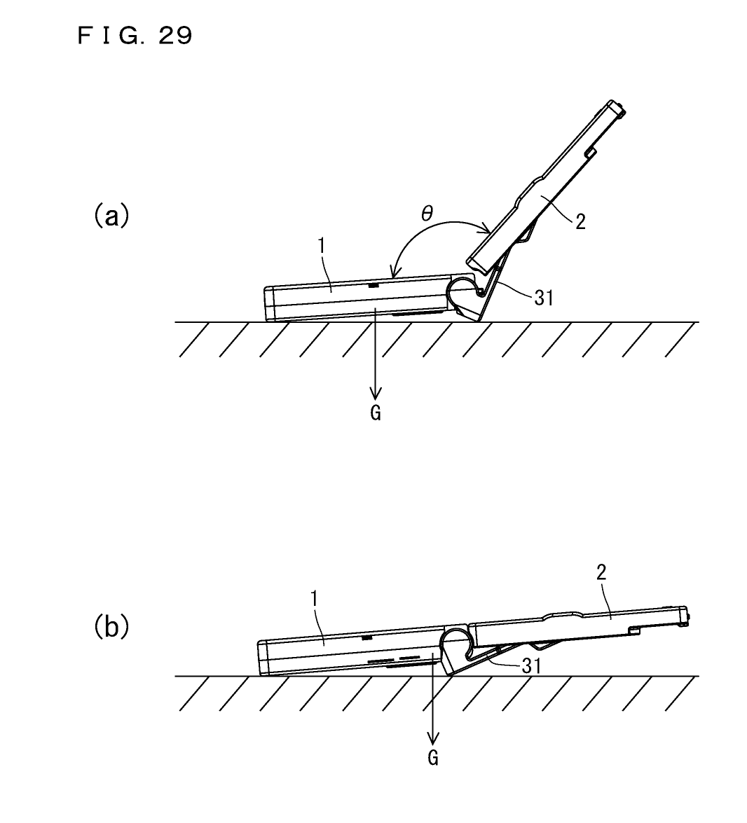

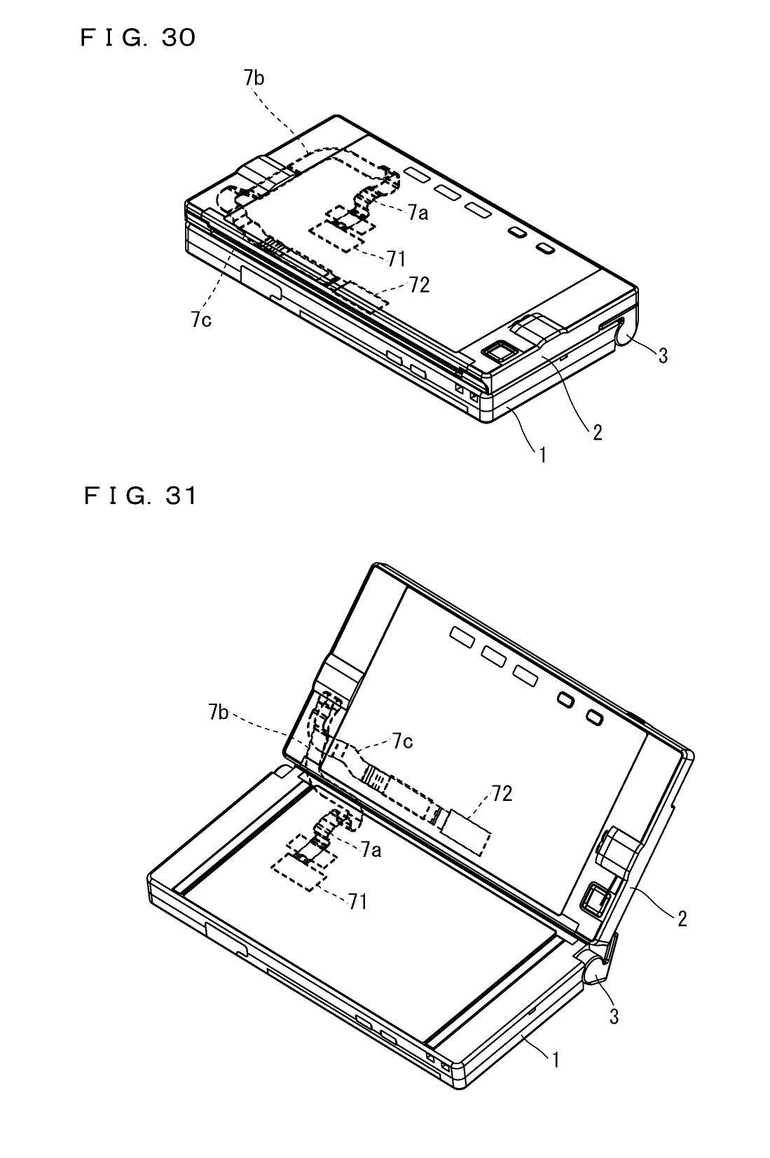

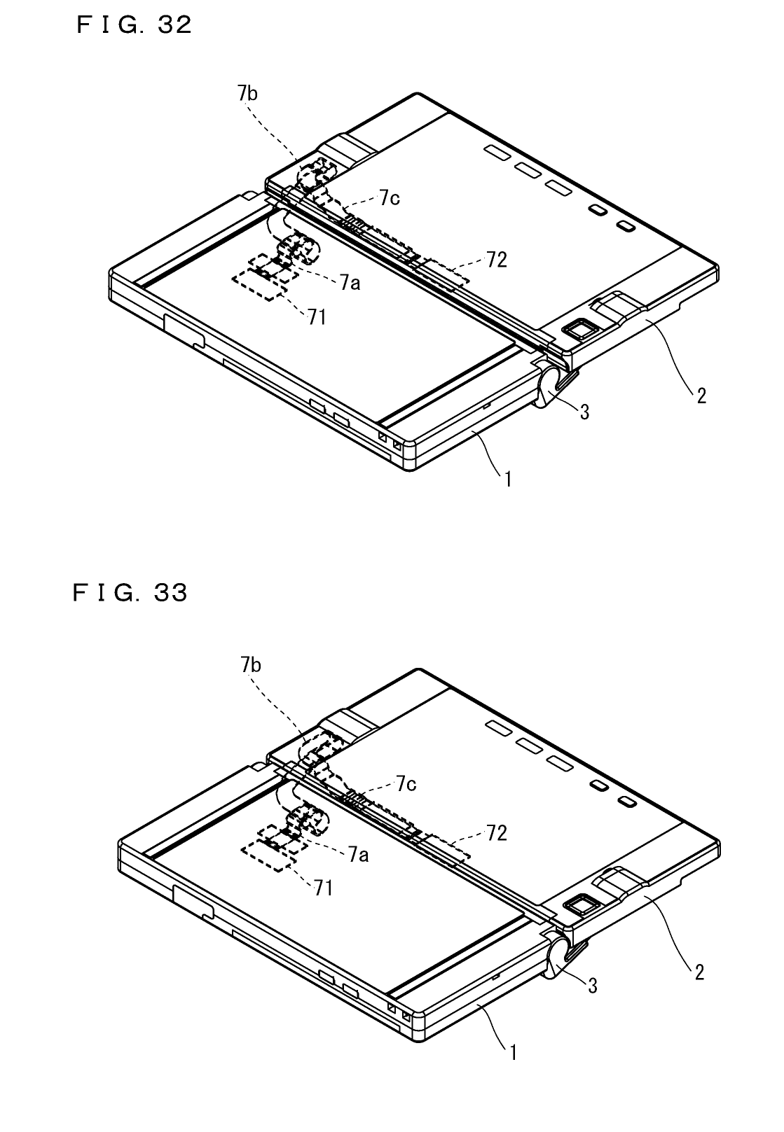

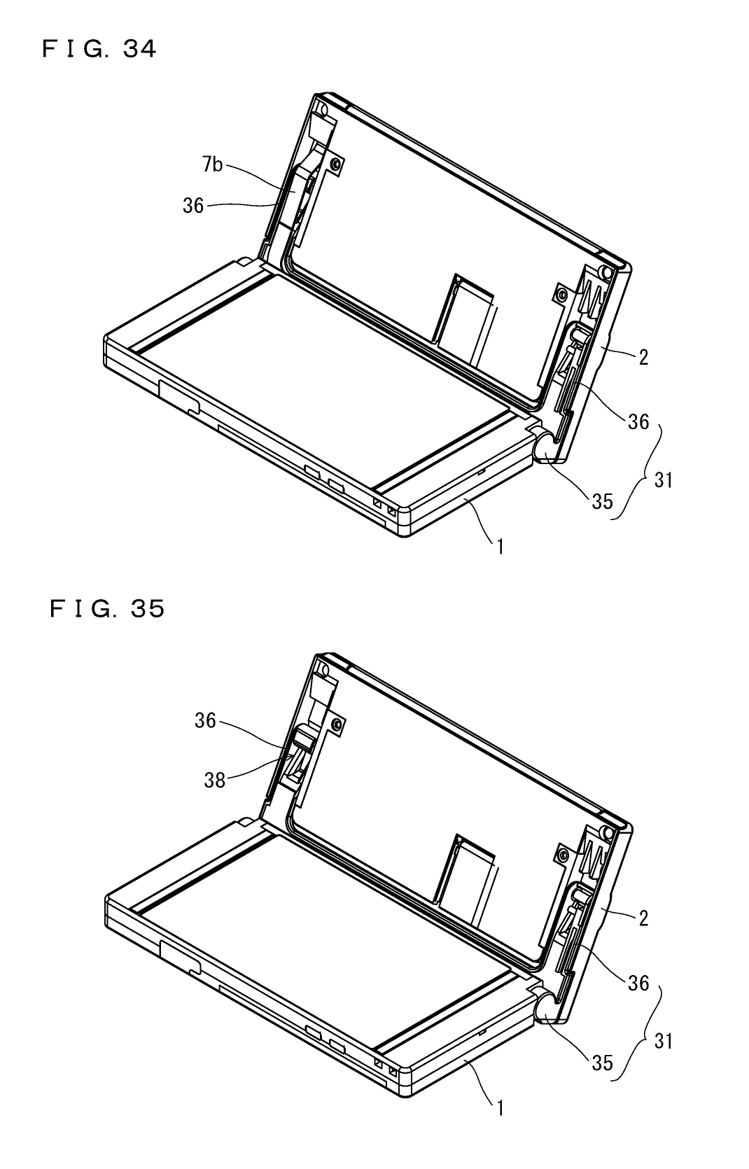

Further, when the above described portable electric device is placed on a desk in a tilted state as shown in FIG. 29(a), or is placed on a desk in a sliding fully open state as shown in FIG. 29(b), the corner portion of the coupling arm 31 protrudes further than the rear face of the first housing 1, thereby causing the front end portion of the first housing 1 and the corner portion of the coupling arm 31 to be grounded.

In this occasion, the layout of the parts and the L-shaped geometry of the coupling arm 31 for the first housing 1 and the second housing 2 are designed such that the center of gravity G is present on the side of the first housing 1 with respect to the grounding point of the coupling arm 31 as shown in any state, thereby stabilizing the posture of both the housings 1 and 2.

Thus, when placed on a desk in a tilted state as shown in FIG. 29(a), it is possible, for example, to operate the touch panel 13 of the first housing 1 in the front while viewing the display 12 of the second housing 2 in the rear.

Moreover, when placed on a desk in a sliding fully open state as shown in FIG. 29(b), both the image display surfaces 11 and 21 come into a posture slightly leaning toward the user depending on the projection amount of the corner portion of the coupling arm 31, thus making it possible to form a single screen with both the image display surfaces 11 and 21 allowing the appreciation of images on a large screen. In this case, since both the image display surfaces 11 and 21 have come sufficiently close to each other, it is possible to display an image without interruption on both the image display surfaces 11 and 21.

The flexible lead 7 is specifically made up of a first lead portion 7a having a belt-shape and extending inside the first housing 1, a second lead portion 7b having a belt-shape and extending in the coupling member of the coupling mechanism 3, and a third lead portion 7c having a belt-shape and extending inside the second housing 2, in which a first coupling portion 71 to be coupled with a connector (omitted from showing) in the first housing 1 is provided in the end portion of the first lead portion 7a, and a second coupling portion 72 to be coupled with a connector (omitted from showing) in the second housing 2 is provided in the end portion of the third lead portion 7c.

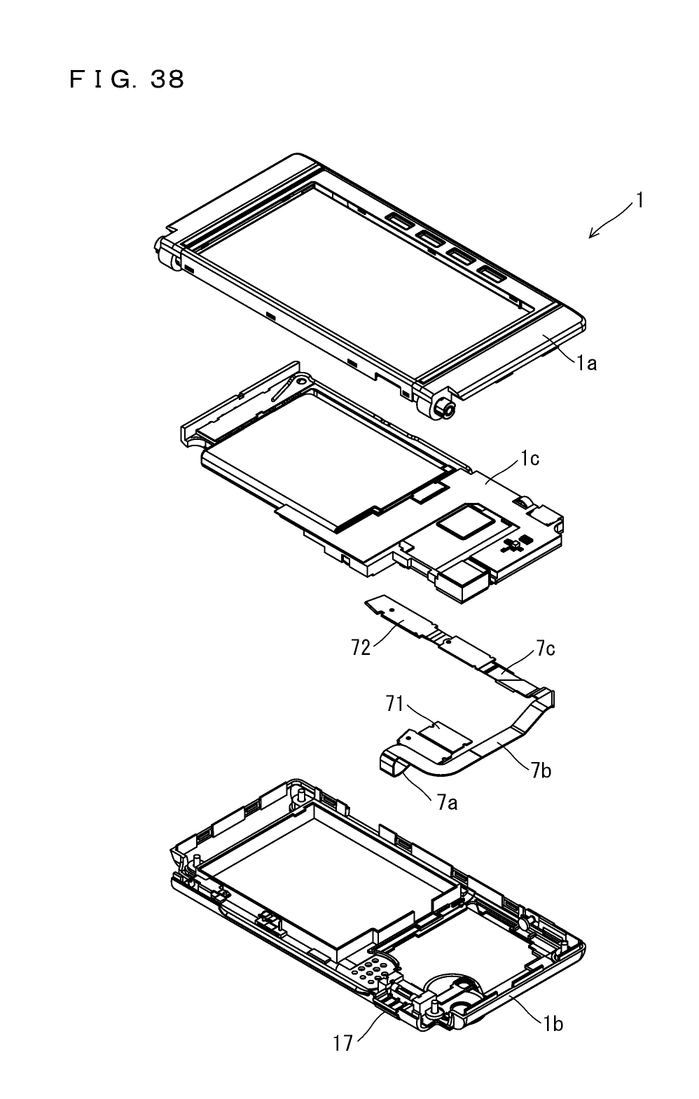

There is a chassis 1c lying between the front cabinet 1a and the rear cabinet 1b, which make up the first housing 1, as shown in FIG. 38. The first coupling portion 71 of the flexible lead 7 is coupled to a connector (omitted from showing) disposed in the back face side of the chassis 1c, and the first lead portion 7a extending from the first coupling portion 71 to the rearward is slightly raised in the first housing 1 as shown in FIG. 31, thereafter extending along the back face of the chassis 1c as shown in FIG. 38, and leading to the second lead portion 7b.

The second lead portion 7b of the flexible lead 7 extends reward toward an arm coupling portion 32a of the coupling member 32 shown in FIG. 9, thereafter bending to the left, extending to the left along the arm coupling portion 32a of the coupling member 32, and thereafter extending in the left-side coupling arm 31 along the second arm portion 36 as shown in FIG. 34.

The third lead portion 7c of the flexible lead 7 extends from the second coupling portion 72 to the left in the front end portion of the second housing 2 in the second housing 2 as shown in FIG. 31, thereafter bending to the side of the rear end portion of the second housing 2, and leading to the second lead portion 7b at the coupling portion between the second housing 2 and the coupling arm 31.

The second arm portion 36 of the coupling arm 31 is formed, on the side of the coupling portion with the second housing 2, with a lead accommodating portion 38 which tolerates the bending deformation of the second lead portion 7b of the flexible lead 7 extending along the second arm portion 36 as shown in FIG. 35.

Moreover, a cover member 17 is openably and closably attached to the end portion of the rear cabinet 1b so as to face the second lead portion 7b of the flexible lead 7.

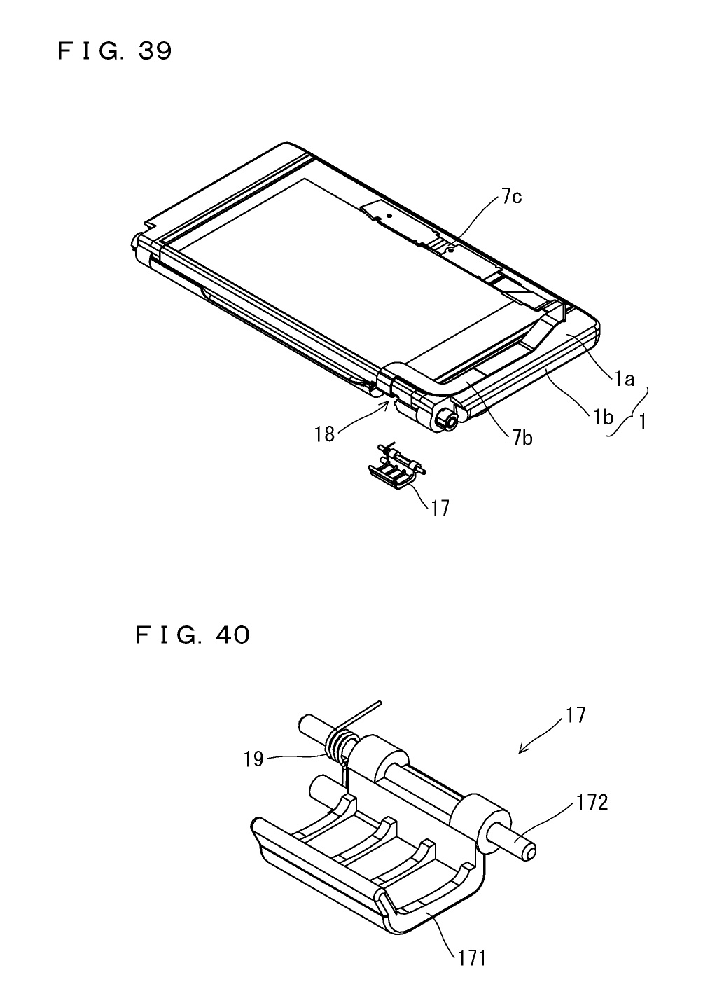

As shown in FIG. 39, the rear cabinet 1b of the first housing 1 is provided with an opening 18 from which the second lead portion 7b of the flexible lead 7 is exposed, and the opening 18 is covered with the cover member 17.

The cover member 17 includes, as shown in FIG. 40, a cover portion 171, a pivot axis 172 provided so as to project from the end portion of the cover portion 171, and a torsion spring 19 attached to one end portion of the pivot axis 172; where both the ends of the pivot axis 172 are axially supported by the rear cabinet 1b of the first housing 1 and both the ends of the torsion spring 19 are engaged by the cover portion 171 and the rear cabinet 1b. As a result of this, the cover portion 171 of the cover member 17 is rotationally biased in the closing direction.

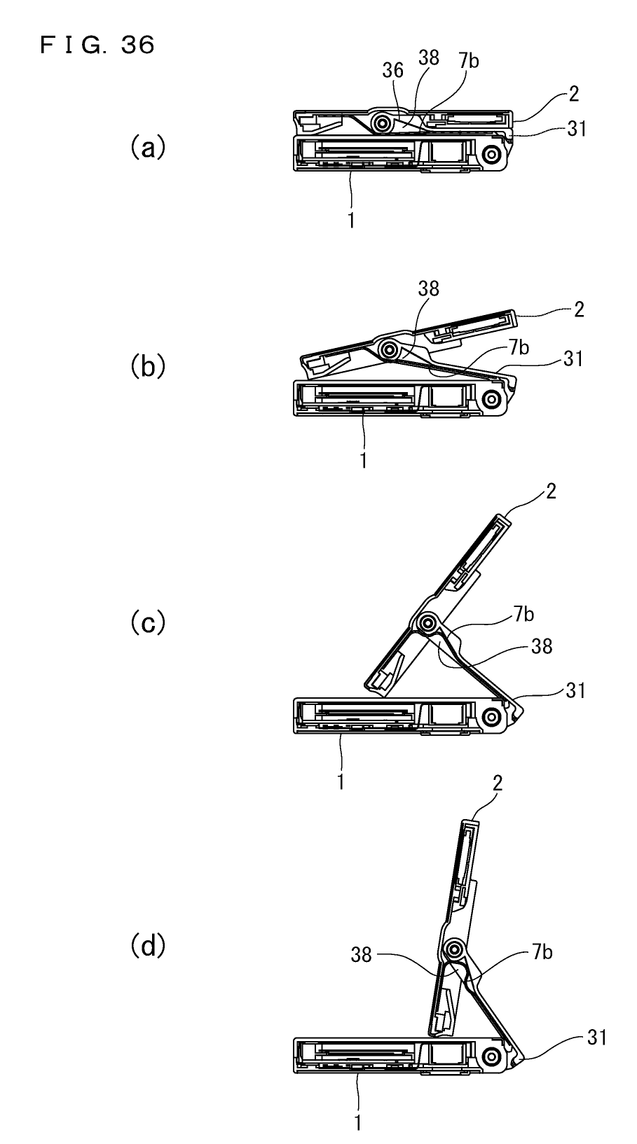

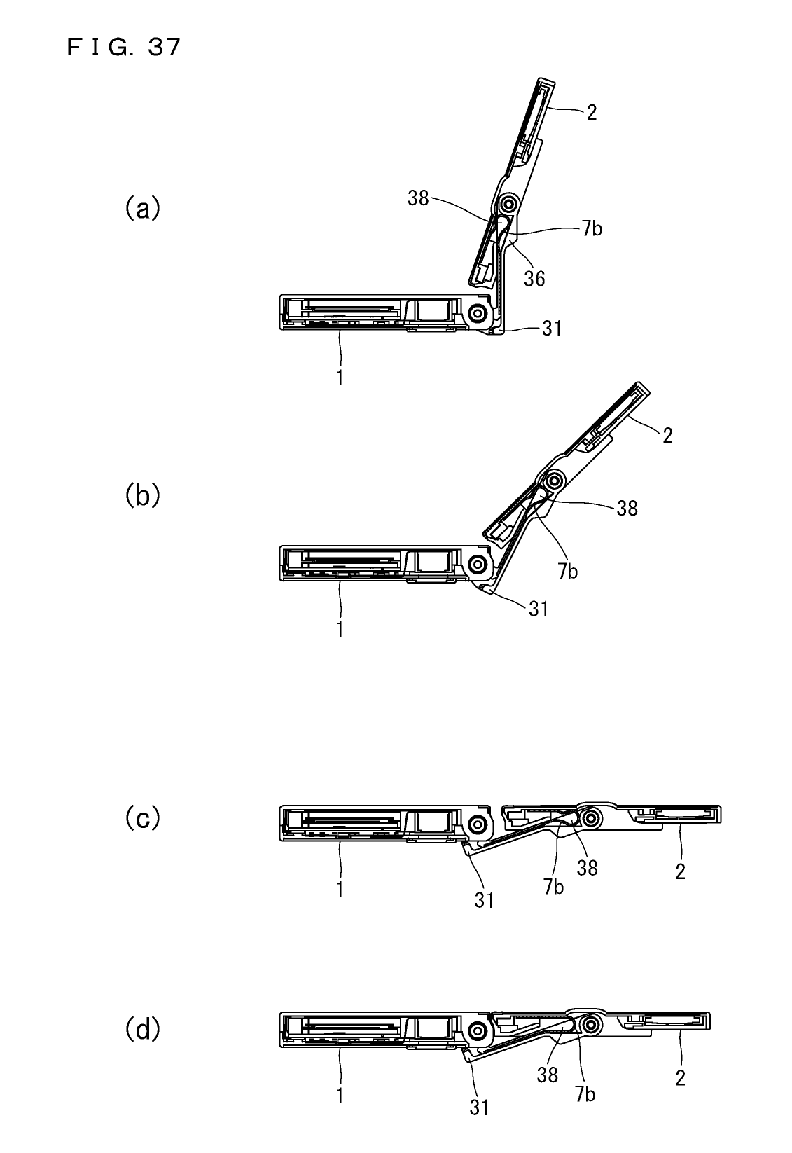

In the above described portable electronic device, since the flexible lead 7 is configured such that the second lead portion 7b extends through the inside of the second arm portion 36 of the coupling arm 31, the flexible lead 7 will undergo bending displacement in association with the pivoting of the coupling arm 31 in the process that both the housings 1 and 2 move from the fully closed state to the sliding fully open state via the tilted state and the pivoting fully open state as shown in FIGS. 36(a) to (d) and FIGS. 37(a) to (d).

In the fully closed state shown in FIG. 36(a), the second lead portion 7b of the flexible lead 7 extends straight inside the second arm portion 36 of the coupling arm 31 to be withdrawn into the second housing 2. When the coupling arm 31 pivots and the second housing 2 starts rising from this state as shown in FIGS. 36(b) and (c), the flexible lead 7 will produce a slack, and the slack is absorbed by the second lead portion 7b undergoing bending deformation in the lead accommodating portion 38 of the coupling arm 31.

Thereafter, in the process of the coupling arm 31 further pivoting to shift to the pivoting fully open state via the tilted state as shown in FIG. 36(d) and FIGS. 37(a) to (c), the flexible lead 7 undergoes a large bending displacement, and the second lead portion 7b will undergo bending and deform into a shape having a plurality of inflection points in the lead accommodating portion 38.

Thus, when reaching the sliding fully open state as shown in FIG. 37(d), the second lead portion 7b of the flexible lead 7 deforms into a U-shaped geometry having an inflection point and is withdrawn into the second housing 2.

As described above, in the process of both the housings 1 and 2 shifting from the fully closed state to the sliding fully open state via the tilted state and the pivoting fully open state, the flexible lead 7 undergoes bending displacement in association with the pivoting of the coupling arm 31, and a slack generated in this process is absorbed by the second lead portion 7b undergoing bending deformation in the lead accommodating portion 38 of the coupling arm 31.

Therefore, there is no need of providing a space for tolerating the bending deformation of the flexible lead 7 in the first housing 1 and the second housing 2.

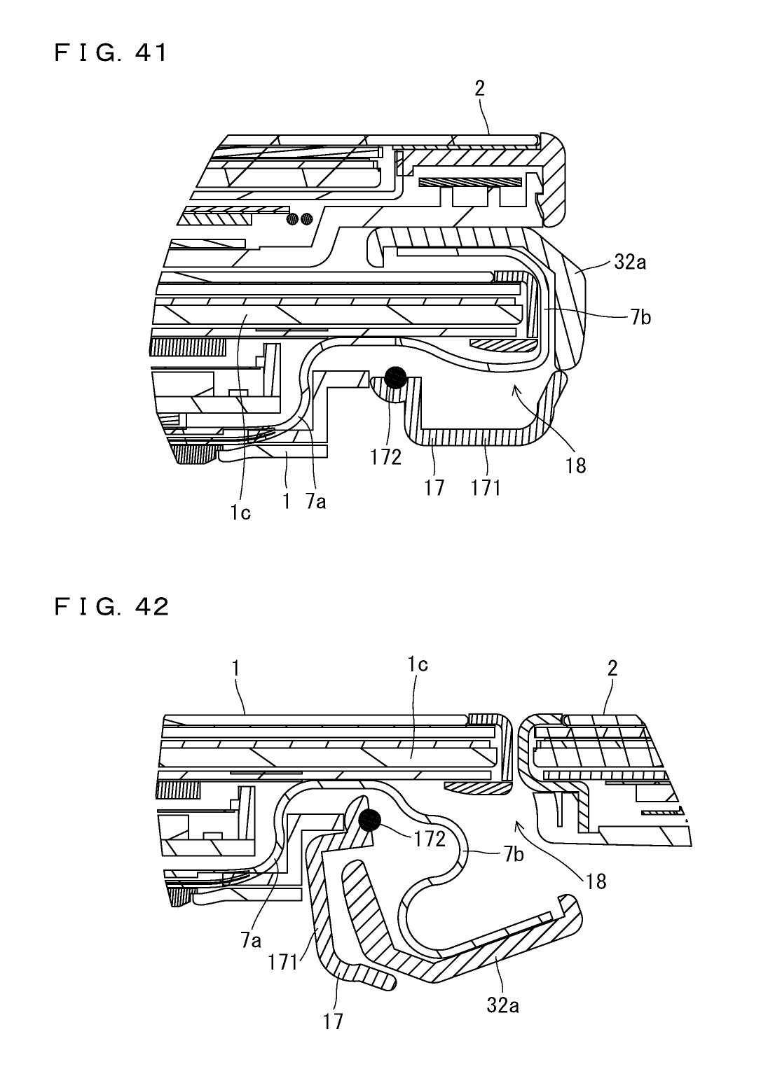

As shown in FIG. 41, when the first housing 1 and the second housing 2 are set to be in the fully closed state, the cover portion 171 of the cover member 17 closes the opening 18 of the first housing 1 due to the above described rotational biasing. At this moment, the arm coupling portion 32a of the coupling member 32 lies between the first housing 1 and the second housing 2.

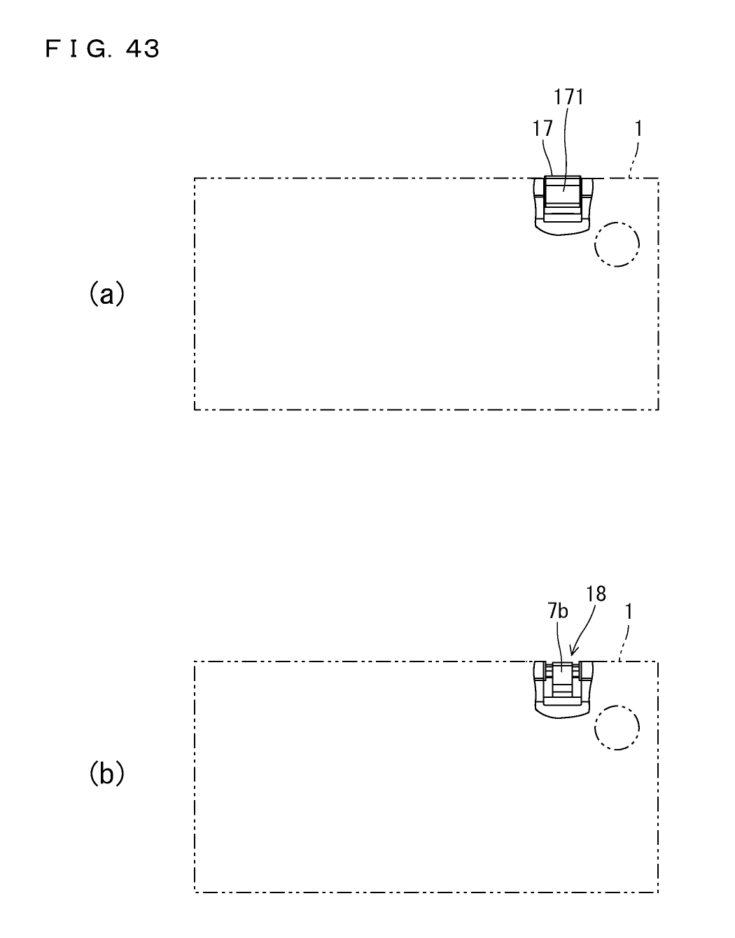

Here, if the cover member 17 is not installed, the second lead portion 7b of the flexible lead 7 will be exposed to the outside from the opening 18 as shown in FIG. 43(b); however, installing the cover member 17 will cause the second lead portion 7b of the flexible lead 7 to be covered by the cover member 17 as shown in FIG. 43(a) thereby preventing the second lead portion 7b from being exposed to the outside.

As shown in FIG. 42, if the first housing 1 and the second housing 2 shift to the fully open state, the coupling member 32 pivots and the arm coupling portion 32a moves to the rear face side of the first housing 1. In association with the movement of the arm coupling portion 32a, the cover portion 171 of the cover member 17 is driven to the opening direction against the rotational biasing described above, and will be opened.

In this state, the arm coupling portion 32a of the coupling member 32 covers the opening 18 of the first housing 1, and the second lead portion 7b of the flexible lead 7 will not be exposed to the outside since it extends inside the arm coupling portion 32a.

It is noted that since the first housing 1 is formed with an opening 18, the second lead portion 7b of the flexible lead 7 can be displaced to the outside of the first housing 1 in association with the movement of the arm coupling portion 32a of the coupling member 32 in the process that the coupling member 32 moves from the position shown in FIG. 41 to the position shown in FIG. 42 in association with the shifting from the fully closed state to the pivoting fully open state. This will enable the second lead portion 7b of the flexible lead 7 to continually lie along the arm coupling portion 32a of the coupling member 32.

The configurations of each component of the present invention will not be limited to the above described embodiments, and can be altered within the technical scope according the claims for the patent. For example, the present invention may be practiced as a portable electronic device which is able to selectively set three states including a fully closed state, a pivoting fully open state, and a sliding fully open state, but not including a tilted state.

### DESCRIPTION OF SYMBOLS

1 First housing

11 First image display surface

17 Cover member

18 Opening

2 Second housing

21 Second image display surface

29 Slide surface

3 Coupling mechanism

32 Coupling member

31 Coupling arm

35 First arm portion

36 Second arm portion

33 Receiving surface

4 Hinge unit

5 Hinge member

6 Torsion spring

7 Flexible lead

8 Slide mechanism

83 Slide member

1. A portable electronic device, in which a first housing and a second housing are coupled with each other via a coupling mechanism, and an image display surface is provided respectively on front faces of both the housings, and which is configured to be able to selectively set at least two states including:
a fully closed state in which the image display surface of the first housing is covered with a back face of the second housing, and the image display surface of the second housing is exposed; and
a fully open state in which the second housing is moved from the fully closed state and the image display surfaces of both the housings are exposed, the portable electronic device configured such that;
the coupling mechanism includes a coupling member that couples the first housing with the second housing so as to be relatively movable between the fully closed state and the fully open state;
an electronic component contained in the first housing, and an electronic component contained in the second housing are electrically connected with each other via lead means; and
the lead means extends inside the coupling member and deforms inside the coupling member in response to a fore-and-aft movement of the coupling member in association with opening and closing of both the housings.

2. A portable electronic device, in which a first housing and a second housing are coupled with each other via a coupling mechanism, and an image display surface is provided respectively on front faces of both the housings, and which is configured to be able to selectively set at least two states including:
a fully closed state in which the image display surface of the first housing is covered with a back face of the second housing, and the image display surface of the second housing is exposed; and
a fully open state in which the second housing is moved from the fully closed state and the image display surfaces of both the housings are exposed, the portable electronic device configured such that;
the coupling mechanism includes a coupling arm which couples the first housing with the second housing so as to be relatively movable between the fully closed state and the fully open state;
an electronic component contained in the first housing, and an electronic component contained in the second housing are electrically connected with each other via a flexible lead, the flexible lead having a belt-like lead portion extending through the inside of the coupling arm; and
the coupling arm is formed with a lead accommodating portion for tolerating a bending deformation of the lead portion in association with opening/closing of both the housings.

3. The portable electronic device according to claim 2, wherein
the first housing and the second housing can be further set into a tilted state in which the second housing is moved from the fully closed state to expose the image display surfaces of both the housings, and the image display surface of the second housing is tilted at an opening angle of not less than 90 degrees and less than 180 degrees with respect to the image display surface of the first housing.

4. The portable electronic device according to claim 2, wherein
the coupling arm has an L-shaped geometry which bends into an L-shape on a plane that perpendicularly intersects with the image display surfaces of both the housings, and includes a first arm portion and a second arm portion which intersect with each other at a corner portion of the L-shaped geometry; the end portion of the first arm portion is coupled to the rear end portion of the first housing with a first pivot axis, and the end portion of the second arm portion is coupled to a middle portion of the second housing between the front end portion and the rear end portion with a second pivot axis which is parallel with the first pivot axis; and the lead accommodating portion is formed in the end portion on the second housing side of the second arm portion.

5. The portable electronic device according to claim 4, wherein
the flexible lead is drawn out from the rear end portion of the first housing, further extends along the first arm portion of the coupling arm, and is drawn into the inside of the second housing from the end portion of the second arm portion.

6. A portable electronic device, in which a first housing and a second housing are coupled with each other via a coupling mechanism, and an image display surface is provided respectively on front faces of both the housings, and which is configured to be able to selectively set at least two states including:
a fully closed state in which the image display surface of the first housing is covered with a back face of the second housing and the image display surface of the second housing is exposed; and
a fully open state in which the second housing is moved from the fully closed state and the image display surfaces of both the housings are exposed, the portable electronic device configured such that;
the coupling mechanism comprises a coupling member that couples the first housing with the second housing so as to be relatively movable between the fully closed state and the fully open state;
an electronic component contained in the first housing and an electronic component contained in the second housing are electrically connected with each other via a flexible lead, the flexible lead extending from the inside of the first housing into the inside of the second housing through inside of the above described coupling member; and
the first housing is formed with an opening which is opened/closed by a reciprocating movement of the coupling member in association with a relative movement of both the housings, and is attached with a cover member that reciprocatingly moves in association with the reciprocating movement of the coupling member so that the cover member closes the opening while the coupling member opens the opening.

7. The portable electronic device according to claim 6, wherein
the cover member is pivotably supported to the first housing and is rotationally biased in the direction to close the opening; and wherein
the cover member opens the opening by being pressed by the coupling member in a process that the coupling member closes the opening in association with the shifting from the fully closed state to the fully open state; and
the cover member is moved by the rotational biasing to close the opening in the process that the coupling member opens the opening in association with the shifting from the fully open state to the fully closed state.

8. The portable electronic device according to claim 6, wherein
the coupling member is configured such that a pair of left and right coupling arm portions are provided at both ends of the arm coupling portion so as to project therefrom;
both ends of each coupling arm are coupled to both the housings; the flexible lead extends from the arm coupling portion along one coupling arm; and
the opening is opened/closed by the arm coupling portion.
